(19) United States
(12) Patent Application Publication
(10) Pub. No.: US 2026/0223644 A1
(43) Pub. Date: Jul. 30, 2026

(54) HIGH DENSITY DIE TO DIE INTERCONNECT SHIFT CORRECTION FOR OVERLAY ALIGNMENT

(71) Applicant: Applied Materials, Inc., Santa Clara, CA (US)

(72) Inventors: Qin ZHONG, Santa Clara, CA (US); Thomas L. LAIDIG, Richmond, CA (US); Chung-Shin KANG, San Jose, CA (US); Jang Fung CHEN, Cupertino, CA (US)

(21) Appl. No.: 19/039,176

(22) Filed: Jan. 28, 2025

(51) Int. Cl. H01L 21/66; H01L 21/48; H01L 23/00; H01L 25/065

(52) U.S. Cl. CPC H10P 74/23; H10W 70/05; H10W 70/092; H10W 70/095; H10W 72/07232; H10W 72/248; H10W 72/252; H10W 72/29; H10W 72/926; H10W 72/9445; H10W 90/00; H10W 90/724

(57) ABSTRACT

A method of forming a DTD interconnect includes measuring a shift in a multi-die interconnect bridge of a partial DTD interconnect. A plurality of via channels and bridge via channels are formed in the build-up layers. A plurality of vias and a plurality of bridge vias are formed in the via channels and the bridge via channels. Interconnect layers are disposed over the plurality of vias and an elongated bridge interconnect is disposed over the plurality of bridge via channels. A plurality of package micro-bump pads and a plurality of bridge micro-bump pads are disposed over the plurality of vias and the bridge vias, respectively. The plurality of vias are aligned with the package micro-bump pads and the plurality of bridge vias are aligned with the plurality of bridge micro-bump pads. One or more dies are bonded to the DTD interconnect.

### BACKGROUND

### Field

Embodiments of the present disclosure generally relate to semiconductor packages and methods of forming the same. More specifically, embodiments described herein relate to methods for correcting X/Y drift in high density die-to-die interconnects.

### Description of the Related Art

Electronic devices, such as are included in tablets, computers, copiers, digital cameras, smart phones, control systems, and automated teller machines, among others, often include integrated circuit die(s) for some desired functionality. Ongoing trends in the development of semiconductor device technologies have led to semiconductor components having reduced sizes and increased circuit densities. In accordance with demands for continued scaling of semiconductor devices while improving performance, these components and circuits are integrated into complex 3D semiconductor device packages that facilitate a significant reduction in device footprint and enable shorter and faster connections between components. Such packages may integrate, for example, semiconductor chips and a plurality of other electronic components for mounting onto a circuit board of an electronic device.

Silicon (Si) bridges have been commonly used for advanced packaging high density die-to-die interconnects. As the interconnect density increases, resulting in a shrinkage of the corresponding micro-bump pitch, any Si bridge shift/rotation will need to be accounted for to enable local level alignment for good overlay performance.

Maskless digital lithography is conventionally used to compensate for Si bridge shift/rotation error. However, the subsequent build-up layers are also susceptible to shift or rotation. This shift or rotation may result in the top layer micro-bump grid being shifted or rotated, such that the top layer micro-bump grid does not match the die micro-bump grid, resulting in poor yield and difficult bonding with the micro-bumps.

Therefore, there is a need in the art for a new compensation mechanism to shift or rotate the subsequent build-up layers back to the original X/Y location.

### SUMMARY

In one embodiments, a method of forming a die-to-die (DTD) interconnect is disclosed. The method includes measuring a shift in a multi-die interconnect bridge of a partial DTD interconnect. The partial DTD interconnect includes a substrate, a plurality of build-up layers disposed over the substrate, a plurality of interconnect layers disposed between the plurality of build-up layers, a plurality of vias disposed in via channels connecting the plurality of interconnect layers, and the multi-die interconnect bridge disposed in a build-up layer of the plurality of build-up layers. A first build-up layer is disposed over the plurality of build-up layers and the multi-die interconnect bridge. A plurality of via channels and bridge via channels are formed in the first build-up layer. A first plurality of vias and a first plurality of bridge vias are formed in the via channels and the bridge via channels. First interconnect layers are disposed over the first plurality of vias and an elongated bridge interconnect is disposed over the first plurality of bridge via channels. A second build-up layer is disposed over the first build-up layer. A plurality of via channels and bridge via channels are formed in the second build-up layer. A plurality of via channels and bridge via channels are formed in the first build-up layer. A second plurality of vias and a second plurality of bridge vias are formed in the via channels and the bridge via channels. A plurality of package micro-bump pads and a plurality of bridge micro-bump pads are disposed over the second plurality of vias and the second bridge vias, respectively. The second plurality of vias are aligned with the package micro-bump pads and the second plurality of bridge vias are aligned with the plurality of bridge micro-bump pads. One or more dies are bonded to the DTD interconnect. The elongated bridge interconnect is configured to span a distance between a position of a plurality of bridge pads of the multi-die interconnect bridge and a nominal position of the plurality of bridge pads caused by a shift in the multi-die interconnect bridge.

In another embodiment, a method for forming a die-to-die (DTD) interconnect is disclosed. The method includes measuring a shift in a multi-die interconnect bridge of a partial DTD interconnect. The partial DTD interconnect includes a substrate, a plurality of build-up layers disposed over the substrate, a plurality of interconnect layers disposed between the plurality of build-up layers, a plurality of vias disposed in via channels connecting the plurality of interconnect layers, and the multi-die interconnect bridge disposed in a build-up layer of the plurality of build-up layers. A first portion of a first build-up layer is disposed over the plurality of build-up layers and the multi-die interconnect bridge. A plurality of bridge via channels are formed in the first portion of the first build-up layer. A first plurality of bridge vias are formed in the bridge via channels. A second portion of the first build-up layer and a first intermediate interconnect layer are disposed over the first portion of the first build-up layer and the first bridge vias. A third portion of the first build-up layer is disposed over the second portion of the first build-up layer. A plurality of via channels are formed in the first build-up layer and bridge via channels in the third portion of the first build-up layer. A first plurality of vias in the via channels and a second plurality of bridge vias are formed in the bridge via channels. A fourth portion of the first build-up layer, a first interconnect layer, and a second intermediate interconnect layer are disposed over the third portion of the first build-up layer. A second build-up layer is disposed over the first build-up layer, first interconnect layer, and second intermediate interconnect layer. A plurality of via channels and a plurality of bridge via channels are formed in the second build-up layer. A second plurality of vias in the via channels and a second plurality of bridge vias are formed in the bridge via channels. A plurality of package micro-bump pads and a plurality of bridge micro-bump pads are disposed over the second plurality of vias and the second bridge vias respectively. The second plurality of vias are aligned with the package micro-bump pads and the second plurality of bridge vias are aligned with the plurality of bridge micro-bump pads. One or more dies are bonded to the DTD interconnect. The first intermediate interconnect layer and the second intermediate interconnect layer are configured to span a distance between a position of a plurality of bridge pads of the multi-die interconnect bridge and a nominal position of the plurality of bridge pads caused by a shift in the multi-die interconnect bridge.

In yet another embodiment, a method for forming a die-to-die (DTD) interconnect is disclosed. The method includes measuring a shift in a multi-die interconnect bridge of a partial DTD interconnect. The partial DTD interconnect includes a substrate, a plurality of build-up layers disposed over the substrate, a plurality of interconnect layers disposed between the plurality of build-up layers, a plurality of vias disposed in via channels connecting the plurality of interconnect layers, and the multi-die interconnect bridge disposed in a build-up layer of the plurality of build-up layers. A first build-up layer is disposed over the plurality of build-up layers and the multi-die interconnect bridge. A plurality of via channels and bridge via channels are formed in the first build-up layer. A first plurality of vias and a first plurality of bridge vias are formed in the via channels and the bridge via channels. First interconnect layers are disposed over the first plurality of vias and a shifted bridge interconnect over the first plurality of bridge via channels. A second build-up layer is disposed over the first build-up layer. A plurality of via channels and bridge via channels are formed in the second build-up layer. A second plurality of vias and a second plurality of bridge vias are formed in the via channels and the bridge via channels. A plurality of package micro-bump pads and a plurality of bridge micro-bump pads are disposed over the second plurality of vias and the second bridge vias, respectively. The second plurality of vias are aligned with the package micro-bump pads and the second plurality of bridge vias are aligned with the plurality of bridge micro-bump pads. One or more dies are bonded to the DTD interconnect. The shifted bridge interconnect is configured to span a distance caused by a shift in the multi-die interconnect bridge.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, cross-sectional view of a die-to-die (DTD) interconnect, according to one or more embodiments.

FIG. 2 is a top cross-sectional view of the DTD interconnect at cut line 2-2, according to one or more embodiments.

FIG. 3 is a top cross-sectional view of the DTD interconnect at cut line 3-3, one or more embodiments.

FIG. 4 is a top cross-sectional view of the DTD interconnect at cut line 4-4, according to one or more embodiments.

FIG. 5 is a top cross-sectional view of the DTD interconnect at cut line 4-4 where a rotated multi-die interconnect bridge has a rotational shift, according to one or more embodiments.

FIG. 6 is a top cross-sectional view of the DTD interconnect at cut line 4-4 where an x-axis shifted multi-die interconnect bridge has an x-axis shift, according to one or more embodiments.

FIG. 7 is an elongated DTD interconnect, according to one or more embodiments.

FIG. 8 is a flow diagram of a method of forming the elongated DTD interconnect, according to one or more embodiments.

FIG. 9A-9J are schematic, cross-sectional view of the elongated DTD interconnect, according to one or more embodiments.

FIG. 10 is an intermediate via DTD interconnect, according to one or more embodiments.

FIG. 11 is a flow diagram of a method of forming the intermediate via DTD interconnect, according to one or more embodiments.

FIG. 12A-12K are schematic, cross-sectional view of the intermediate via DTD interconnect, according to one or more embodiments.

FIG. 13 is a shifted via DTD interconnect, according to one or more embodiments.

FIG. 14 is a flow diagram of a method 1400 of forming the intermediate via DTD interconnect, according to one or more embodiments.

FIG. 15A-15J are schematic, cross-sectional view of the intermediate via DTD interconnect, according to one or more embodiments.

FIG. 16A is a perspective view of a photolithography system, according to one or more embodiments.

FIG. 16B is a perspective view of a photolithography system, according to one or more embodiments.

FIG. 17A is a perspective schematic view of an image projection apparatus, according to one or more embodiments.

FIG. 17B is an image project apparatus, according to one or more embodiments.

FIG. 18 is a controller, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to semiconductor packages and methods of forming the same. More specifically, embodiments described herein relate to methods for compensating for X/Y drift in high density die-to-die interconnects.

In certain embodiments, a method of compensating for X/Y drift in high density die-to-die interconnects is disclosed. The method utilizes a maskless direct-writing tool that calculates, based on micro-bump pitch, via dimensions, lithography overlay error, and number of steps, the rotation of the build-up layers needed to return a top layer micro-bump grid to the nominal X/Y location. The method compensates for randomized die shift/rotation error, and approximately restores the top layer to the nominal X/Y position, such that the micro-bump grid attaches to the die, in a controlled manner via the maskless direct-writing lithography tool.

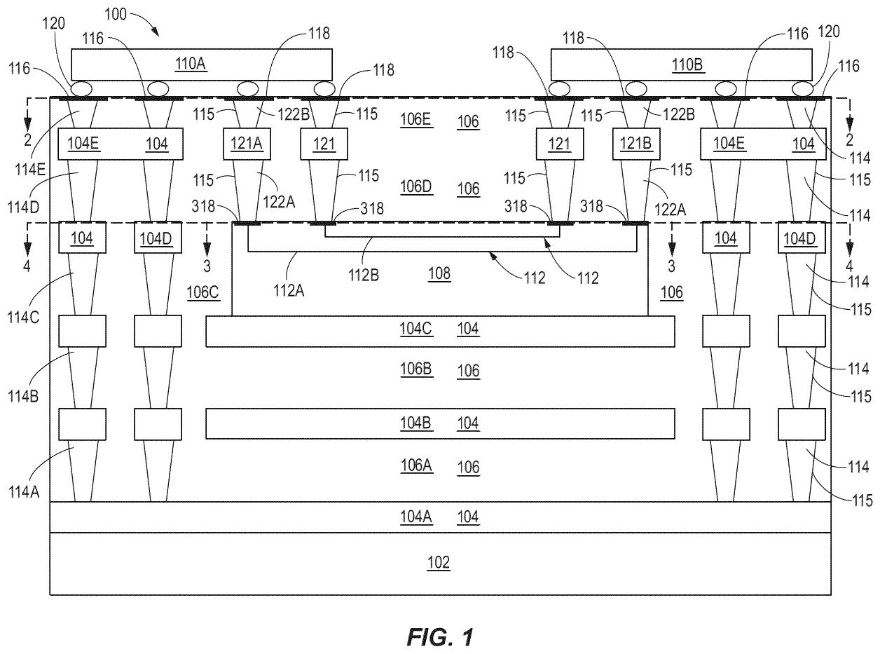

FIG. 1 is a schematic, cross-sectional view of a die-to-die (DTD) interconnect 100. In some examples, the DTD interconnect 100 is a high density DTD interconnect. The DTD interconnect 100 includes a substrate 102, a plurality of interconnect layers 104, a plurality of build-up layers 106, a multi-die interconnect bridge 108, a plurality of package micro-bump pads 116, a plurality of bridge micro-bump pads 118, and a plurality of bridge pads 318. In some examples, the plurality of interconnect layers 104 include a first interconnect layer 104A, a second interconnect layer 104B, a third interconnect layer 104C, a fourth interconnect layer 104D, and a fifth interconnect layer 104E. In some examples, the plurality of build-up layers 106 include a first build-up layer 106A, a second build-up layer 106B, a third build-up layer 106C, a fourth build-up layer 106D, and a fifth build-up layer 106E. The first interconnect layer 104A is disposed over the substrate 102. The first build-up layer 106A is disposed over the first interconnect layer 104A. The second interconnect layer 104B is disposed over the first build-up layer 106A. The second build-up layer 106B is disposed over the second interconnect layer 104B. The third interconnect layer 104C is disposed over the second build-up layer 106B. The third build-up layer 106C is disposed over the third interconnect layer 104C. The fourth interconnect layer 104D is disposed over the third build-up layer 106C. The fourth build-up layer 106D is disposed over the fourth interconnect layer 104D. The fifth interconnect layer 104E and a bridge interconnect layer 121 are disposed over the fourth build-up layer 106D. The fifth build-up layer 106E is disposed over the fifth interconnect layer 104E and the bridge interconnect layer 121. The interconnect layers 104 and bridge interconnect layer 121 include a copper material, an epoxy, such as an Ajinomoto Build-up Film (ABF), or a photo image-able dielectric (PID) and the build-up layers 106 include a dielectric material, such as a polyimide material or an epoxy, such as ABF. The plurality of package micro-bump pads 116 and the plurality of bridge micro-bump pads 118 are disposed over the fifth build-up layer 106E. The plurality of package micro-bump pads 116 and the plurality of bridge micro-bump pads 118 include a solder material or copper material.

The multi-die interconnect bridge 108 is embedded in one of the plurality of build-up layers 106, e.g., the fourth build-up layer 106D. In some examples, the multi-die interconnect bridge 108 is a silicon bridge. The multi-die interconnect bridge 108 includes bridge interconnects 112, such as first bridge interconnect 112A and second bridge interconnect 112B. A plurality of vias 114 are disposed in via channels 115 to connect the interconnect layers 104 and to connect the interconnect layers 104 to the plurality of package micro-bump pads 116. In one example, a plurality of first vias 114A connect the first interconnect layer 104A to the second interconnect layer 104B, a plurality of second vias 114B connect the second interconnect layer 104B to the third interconnect layer 104C, a plurality of third vias 114C connect the third interconnect layer 104C to the fourth interconnect layer 104D, and a plurality of fourth vias 114D connect the fourth interconnect layer 104D to the fifth interconnect layer 104E. A plurality of fifth vias 114E connect the fifth interconnect layer 104E to the plurality of package micro-bump pads 116.

One or more first bridge vias 122A are disposed in the via channels 115 to connect the bridge pads 318 of the multi-die interconnect bridge 108 to the bridge interconnect layer 121. One or more second bridge vias 122B are disposed in the via channels 115 to connect the bridge interconnect layer 121 to the plurality of bridge micro-bump pads 118. The plurality of bridge pads 318 include a copper material or a solder material. The vias 114, first bridge vias 122A, and second bridge vias 122B include an electrically conductive material, such as copper, alloys thereof, or a combination thereof.

The DTD interconnect 100 may be connected to one or more dies, e.g., a first die 110A and a second die 110B. The first die 110A and the second die 110B are connected to the DTD interconnect 100 via the plurality of package micro-bump pads 116 and the plurality of bridge micro-bump pads 118. The first die 110A and the second die 110B may include various components, such as transistors, diodes, resistors, or other electrical components. The first die 110A and the second die 110B are connected to the plurality of package micro-bump pads 116 and to the plurality of bridge micro-bump pads 118 by a plurality of micro-bumps 120 using thermo-compression bonding or hybrid bonding. The micro-bumps 120 include tin-lead (SnPb) materials, tin-silver (SnAg) materials, tin-silver-copper (SAC) materials, gold-tin materials (AuSn), copper pillar (Cu-pillar), alloys thereof, or combinations thereof. In some examples, Si Bridge approaches use solder bumps. Solder bumps are typically associated with a higher electrical resistance than a direct Cu junctions. The input/output area density is limited by solder bump pitch. The bump pitch (e.g., the horizontal, center-to-center distance, or the sum of the bump width and bump spacing) is less than about 100 microns, such as about 35 microns to about 50 microns, such as less than 50 microns, such as about 20 micron to about 30 microns, such as about less than 10 microns. In some examples, Si Bridge approaches use solder bumps.

In some examples, the bridge interconnect layer 121 includes a first die interconnect layer 121A and a second die interconnect layer 121B. The first die interconnect layer 121A is disposed between and electrically connects the multi-die interconnect bridge 108 to the first die 110A. The second die interconnect layer 121B is disposed between and electrically connects the multi-die interconnect bridge 108 to the second die 110B.

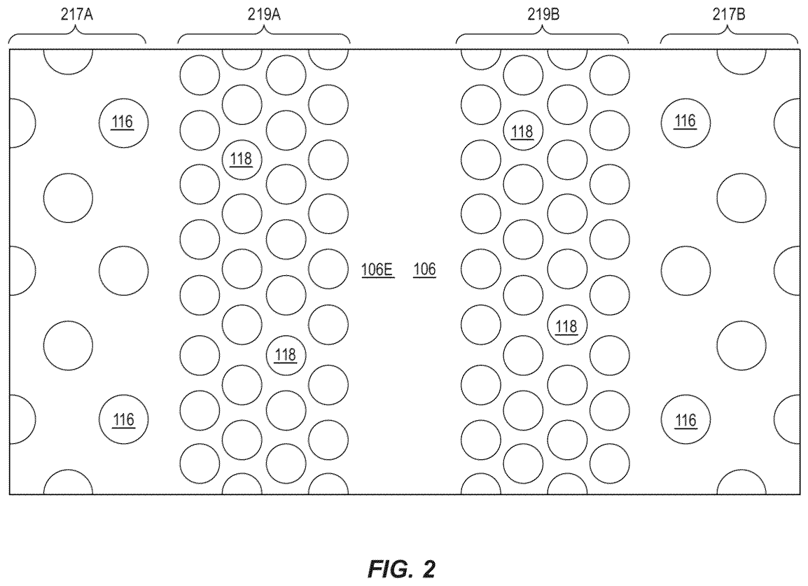

FIG. 2 is a top cross-sectional view of the DTD interconnect 100 at cut line 2-2. The plurality of package micro-bump pads 116 and the plurality of bridge micro-bump pads 118 form a first package micro-bump grid 217A, a second package micro-bump grid 217B, a first bridge micro-bump grid 219A, and a second bridge micro-bump grid 219B. Each package micro-bump pad 116 and bridge micro-bump pad 118 are bonded to one of the plurality of micro-bumps 120.

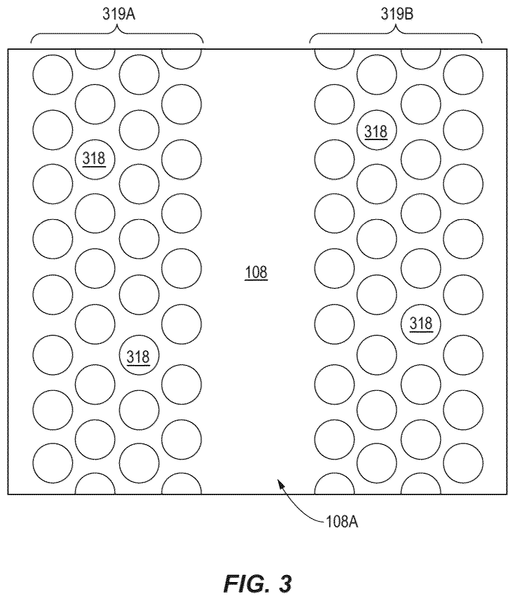

FIG. 3 is a top cross-sectional view of the DTD interconnect 100 at cut line 3-3. The multi-die interconnect bridge 108 includes the plurality of bridge pads 318 on an upper surface 108A of the multi-die interconnect bridge 108. In some examples, the plurality of bridge pads 318 form a first bridge pad grid 319A and a second bridge pad grid 319B. One or more first bridge vias 122A connect the bridge pads 318 of the multi-die interconnect bridge 108 to the bridge interconnect layer 121.

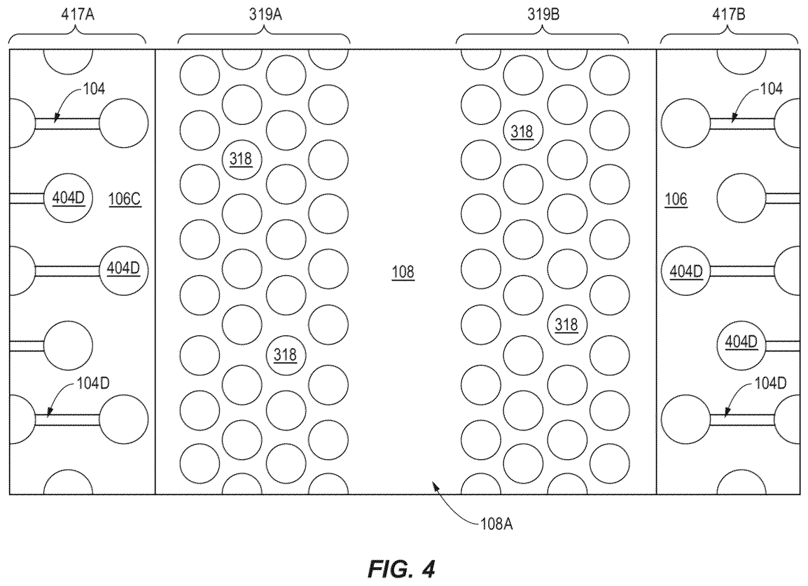

FIG. 4 is a top cross-sectional view of the DTD interconnect 100 at cut line 4-4. A plurality of interconnect pads 404D of the fourth interconnect layer 104D form a first interconnect grid 417A and a second interconnect grid 417B. The first interconnect grid 417A and the second interconnect grid 417B are connected to the fifth interconnect layer 104E through the plurality of fourth vias 114D, and the fifth interconnect layer 104E is connected to the first package micro-bump grid 217A and second package micro-bump grid 217B through the plurality of fifth vias 114E. The multi-die interconnect bridge 108, therefore, creates an electrical transmission pathway between the first interconnect grid 417A and the second interconnect grid 417B. The DTD interconnect 100 is capable of sending electrical signals from the first interconnect grid 417A to the first package micro-bump grid 217A via the plurality of fourth vias 114D and the plurality of fifth vias 114E. The first die 110A receives the electrical signal from the first package micro-bump grid 217A via the micro-bumps 120 bonded to the plurality of package micro-bump pads 116. The first die 110A transmits the signal to the first bridge micro-bump grid 219A. The first bridge pad grid 319A of the multi-die interconnect bridge 108 receives the electrical signal from the first bridge micro-bump grid 219A via the second bridge vias 122B, the bridge interconnect layer 121, and the first bridge vias 122A. The multi-die interconnect bridge 108 transmits the electrical signal from the first bridge pad grid 319A to the second bridge pad grid 319B via the bridge interconnects 112, such as first bridge interconnect 112A and second bridge interconnect 112B. The second bridge micro-bump grid 219B receives the electrical signal from the second bridge pad grid 319B of the multi-die interconnect bridge 108 via the first bridge vias 122A, the bridge interconnect layer 121, and the second bridge vias 122B. The second die 110B receives the electrical signal from the second bridge micro-bump grid 219B via the micro-bumps 120 and transmits the signal to the second package micro-bump grid 217B.

Si Bridge packaging is a type of semiconductor packaging technology that enables the integration of multiple dies or chips on a single package using a 2.5D or 3D layout. This approach involves using a silicon interposer or “bridge” that provides high-density electrical connections between the dies and other components, such as memory or sensors. In a 2.3D Si Bridge package, the interposer is thinned down to reduce the distance between the dies and minimize electrical parasitics, resulting in improved performance and power efficiency. However, by increasing the interconnect density, the pitch of the micro-bumps 120 connecting the first die 110A and the second die 110B to the DTD interconnect 100 is decreased. Therefore, any rotation or shift in the multi-die interconnect bridge 108 could decrease the effectiveness of the bond between the micro-bumps 120 and the plurality of package micro-bump pads 116 and to the plurality of bridge micro-bump pads 118.

The shift or rotation may be the results of various challenges in DTD interconnect fabrication. Machine mechanical motions, fiducial recognitions, and thermal processes associated with cavity structures, dielectric materials (e.g., build-up layer material), and encapsulations may cause inaccuracies the registration of the multi-die interconnect bridge 108. The profile of the multi-die interconnect bridge 108 under different process conditions, driven by coefficients of thermal expansion, may result in die warpage control issues. Via formation alignment is performed in the build-up layer above the multi-die interconnect bridge 108. Therefore, indirect alignment occurs between the vias 114 and the plurality of package micro-bump pads 116. Errors in this alignment may be caused by errors in multi-die interconnect bridge 108 embedding, dielectric (e.g., build-up layer) encapsulation errors, laser/lithography errors, or other associated processing tool errors. As bump pitch scaling continues, increased device to device communication (e.g., more multi-die interconnect bridges 108) and larger size die stitching capabilities are required. This requires increased tightening of the tolerances for via-to-pad overlay alignment.

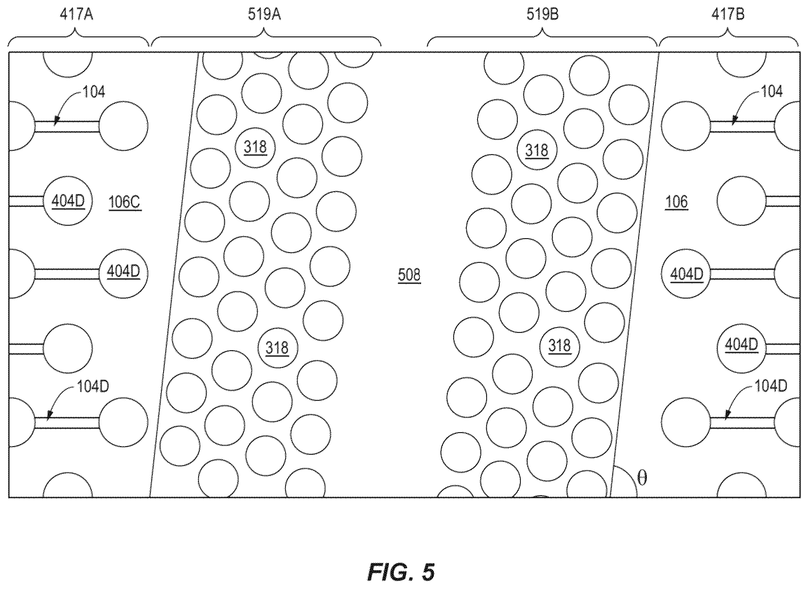

FIG. 5 is a top cross-sectional view of the DTD interconnect 100 at cut line 4-4 where a rotated multi-die interconnect bridge 508 has a rotational shift. The rotated multi-die interconnect bridge 508 includes a first rotated bridge pad grid 519A and a second rotated bridge pad grid 519B. The rotational shift has a shift angle θ. The shift angle θ could be any angle from 1° to about 45°.

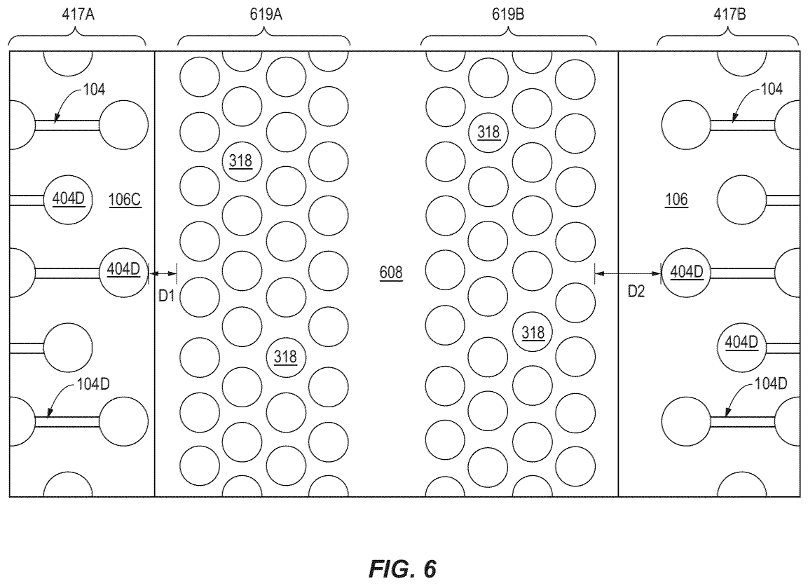

FIG. 6 is a top cross-sectional view of the DTD interconnect 100 at cut line 4-4 where an x-axis shifted multi-die interconnect bridge 108 has an x-axis shift. The x-axis shift results in a first distance D1 between a first bridge pad grid 619A and a first interconnect grid 417A to be larger than the second distance D2 between the second bridge pad grid 619B and a second intermediate grid 417B. In another example, the x-axis shift results in the first distance D1 being larger than the second distance D2. In another example, the multi-die interconnect bridge 108 has a y-axis shift. In yet another example, the multi-die interconnect bridge 108 has an x-axis shift, a y-axis shift, a rotational shift, or a combination thereof.

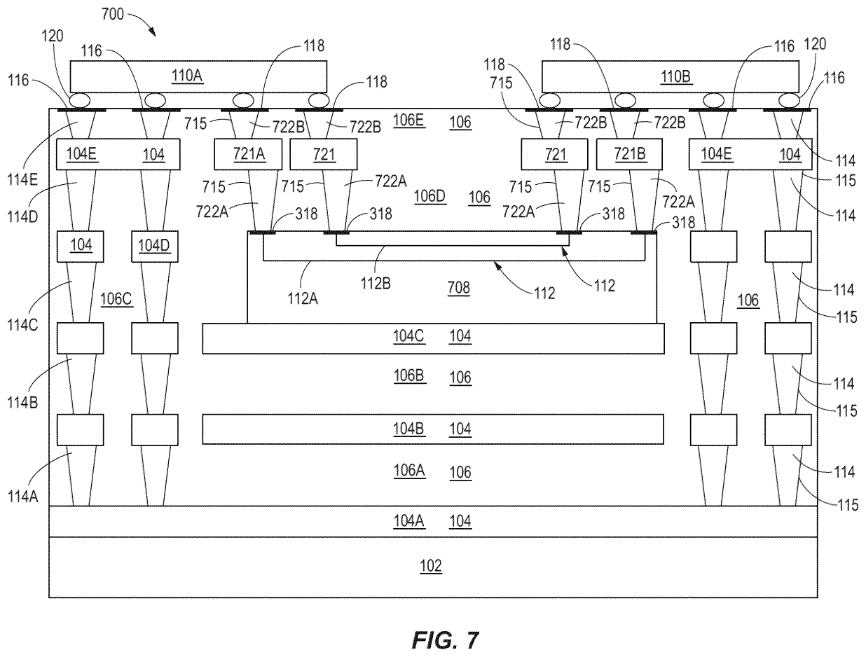

FIG. 7 is an elongated DTD interconnect 700. The elongated DTD interconnect 700 utilizes an elongated bridge interconnect layer 721 to connect a first bridge vias 722A and a second bridge vias 722B. The elongated bridge interconnect layer 721 includes a first elongated bridge interconnect layer 721A and a second elongated die interconnect layer 721B. The first elongated bridge interconnect layer 721A is disposed between and electrically connects the multi-die interconnect bridge 108 to the first die 110A. The second elongated die interconnect layer 721B is disposed between and electrically connects the multi-die interconnect bridge 108 to the second die 110B. One or more first bridge vias 722A are disposed in bridge via channels 715 to connect the bridge pads 318 of the multi-die interconnect bridge 708 to the elongated bridge interconnect layer 721. One or more second bridge vias 722B are disposed in the bridge via channels 715 to connect the elongated bridge interconnect layer 721 to the plurality of bridge micro-bump pads 118. The elongated bridge interconnect layer 721 spans between the one or more first bridge vias 722A and the one or more second bridge vias 722B to compensate for an x-axis shift, a y-axis shift, a rotational shift, or a combination thereof of the shifted multi-die interconnect bridge 708. The shifted multi-die interconnect bridge 708 may the rotated multi-die interconnect bridge 508, the x-axis shifted multi-die interconnect bridge 608, or a shifted multi-die interconnect bridge having an x-axis shift, a y-axis shift, a rotational shift, or a combination thereof.

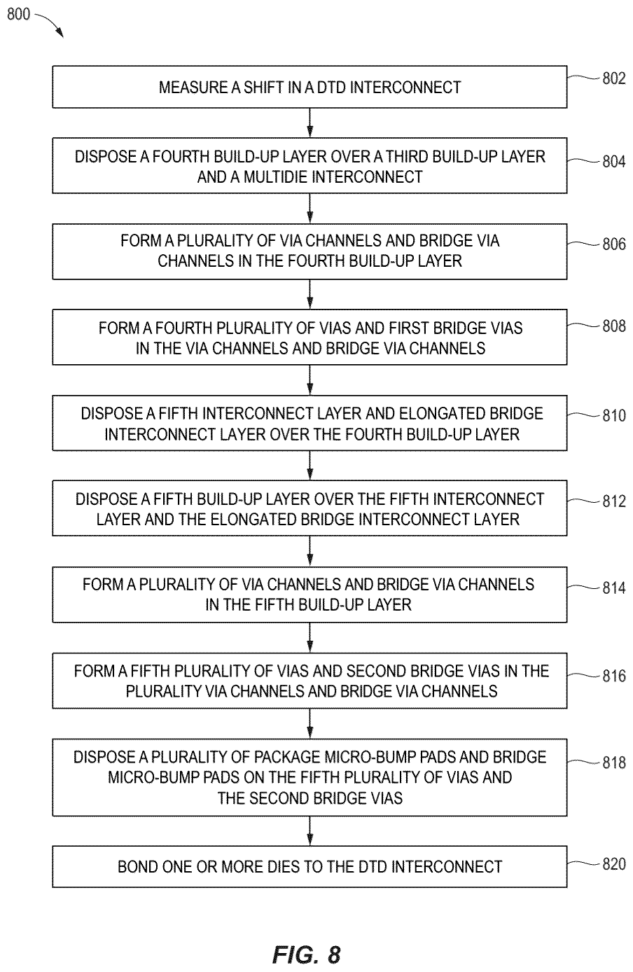

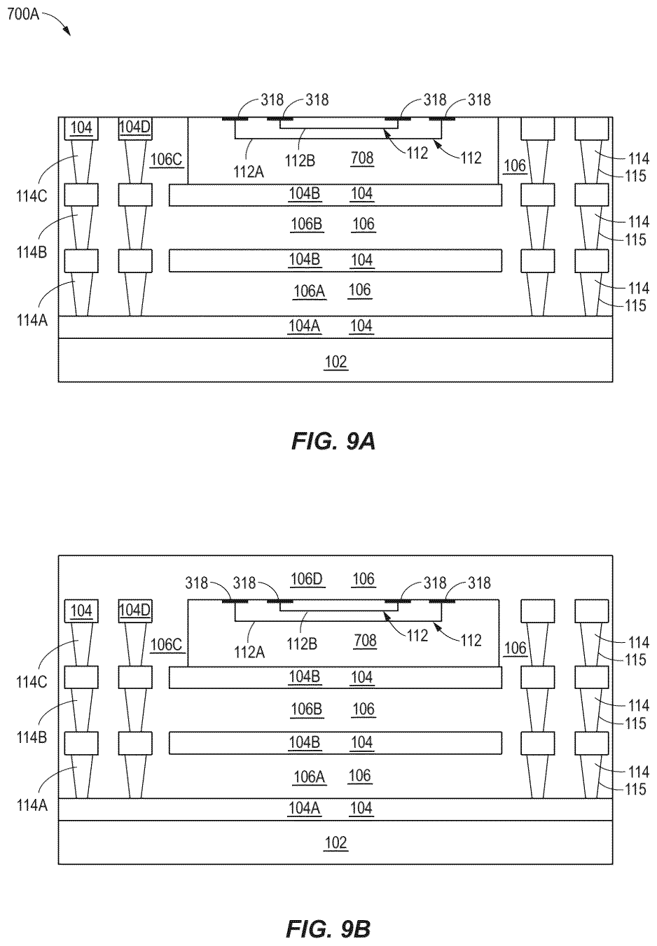

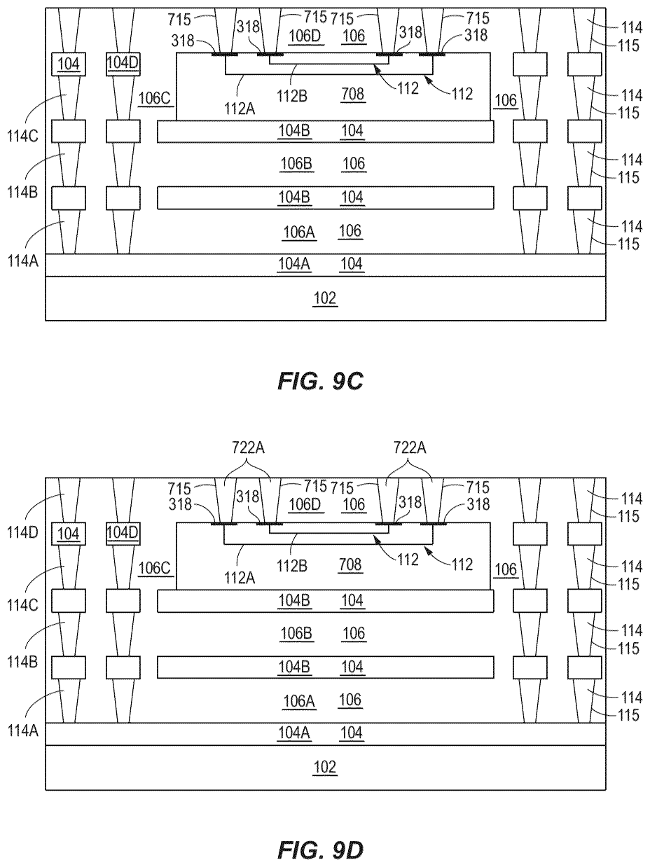

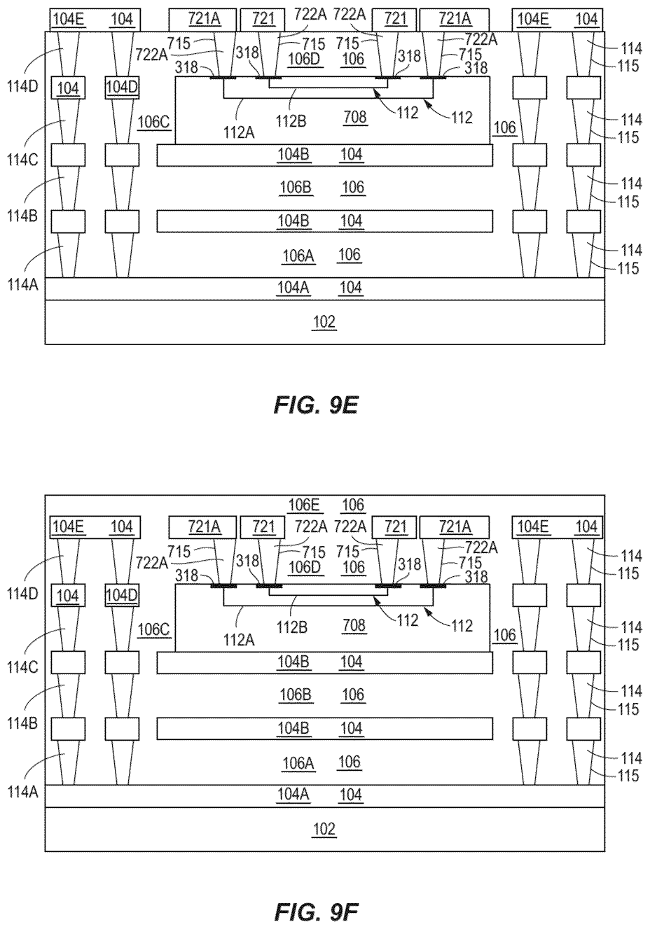

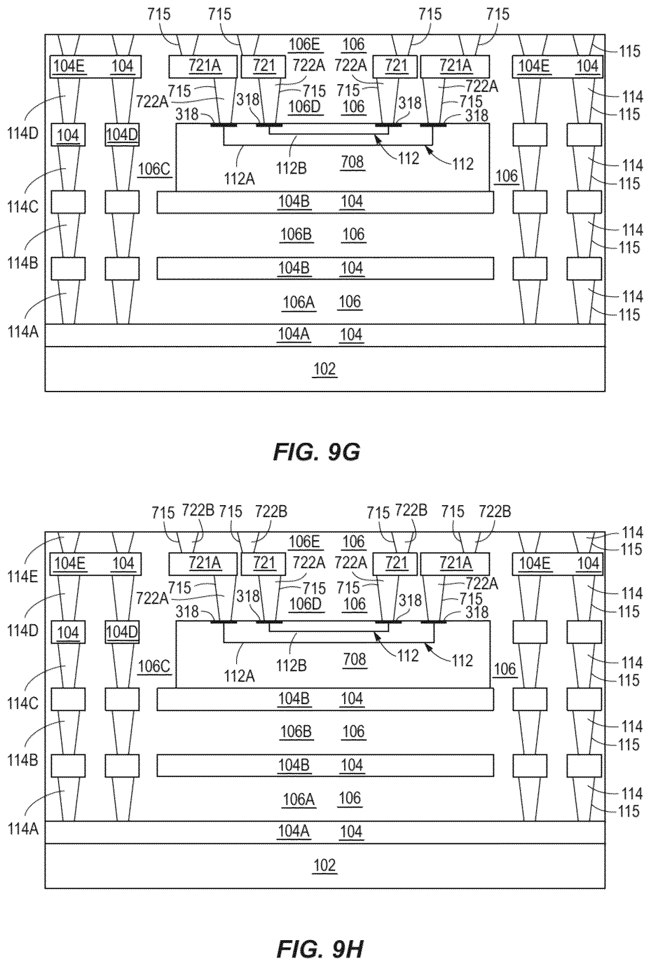

FIG. 8 is a flow diagram of a method 800 of forming the elongated DTD interconnect 700. FIG. 9A-9J are schematic, cross-sectional view of the elongated DTD interconnect 700. The method 800 may be performed using a photolithography system 1600A or a photolithography system 1600B.

At operation 802 the shift of a partial elongated DTD interconnect 700A, as shown in FIG. 9A, is measured. In one example, at operation 802, the partial elongated DTD interconnect 700A includes a substrate 102, a first interconnect layer 104A, a second interconnect layer 104B, a third interconnect layer 104C, a fourth interconnect layer 104D, a first build-up layer 106A, a second build-up layer 106B, and a third build-up layer 106C. The shifted multi-die interconnect bridge 708 is embedded in the third build-up layer 106C. The shifted multi-die interconnect bridge 708 includes bridge interconnects 112, such as first bridge interconnect 112A and second bridge interconnect 112B.

The shift is measured within the photolithography system 1600A or the photolithography system 1600B using a metrology system, such as a camera. The metrology system measures the position of the plurality of bridge pads 318 of the shifted multi-die interconnect bridge 708 against a nominal position. The nominal position is the position at which the micro-bumps 120 are configured to be connected to the plurality of bridge micro-bump pads 118. The metrology system calculates the differential between the measured position of the plurality of bridge pads 318 and the nominal position of the plurality of bridge micro-bump pads 118.

At operation 804, as shown in FIG. 9B, a fourth build-up layer 106D is disposed over the third build-up layer 106C and the shifted multi-die interconnect bridge 708. The fourth build-up layer 106D is deposited using lamination or slit coating.

At operation 806, as shown in FIG. 9C, a plurality of via channels 115 and a plurality of bridge via channels 715 are formed in the fourth build-up layer 106D. The plurality of bridge via channels are formed using a laser drilling machine or a lithography machine including a stepper, a laser direct imaging (LDI), or digital lithography.

At operation 808, as shown in FIG. 9D, a plurality of fourth vias 114D and first bridge vias 722A are formed in the via channels 115 and the bridge via channels 715.

At operation 810, as shown in FIG. 9E, a fifth interconnect layer 104E and elongated bridge interconnect layer 721 is disposed over the fourth build-up layer 106D.

At operation 812, as shown in FIG. 9F, a fifth build-up layer 106E is disposed over the fifth interconnect layer 104E and elongated bridge interconnect layer 721.

At operation 814, as shown in FIG. 9G, a plurality of via channels 115 and a plurality of bridge via channels 715 are formed in the fifth build-up layer 106E.

At operation 816, as shown in FIG. 9H, a plurality of fifth vias 114E and second bridge vias 722B are formed in the via channels 115 and the bridge via channels 715.

At operation 818, as shown in FIG. 91, a plurality of package micro-bump pads 116 and a plurality of bridge micro-bump pads 118 are disposed over the plurality of fifth vias 114E.

At operation 820, as shown in FIG. 9J, one or more dies (e.g., a first die 110A and a second die 110B) are bonded to the elongated DTD interconnect 700. The first die 110A and the second die 110B are bonded to the plurality of package micro-bump pads 116 and a plurality of bridge micro-bump pads 118 via micro-bumps 120.

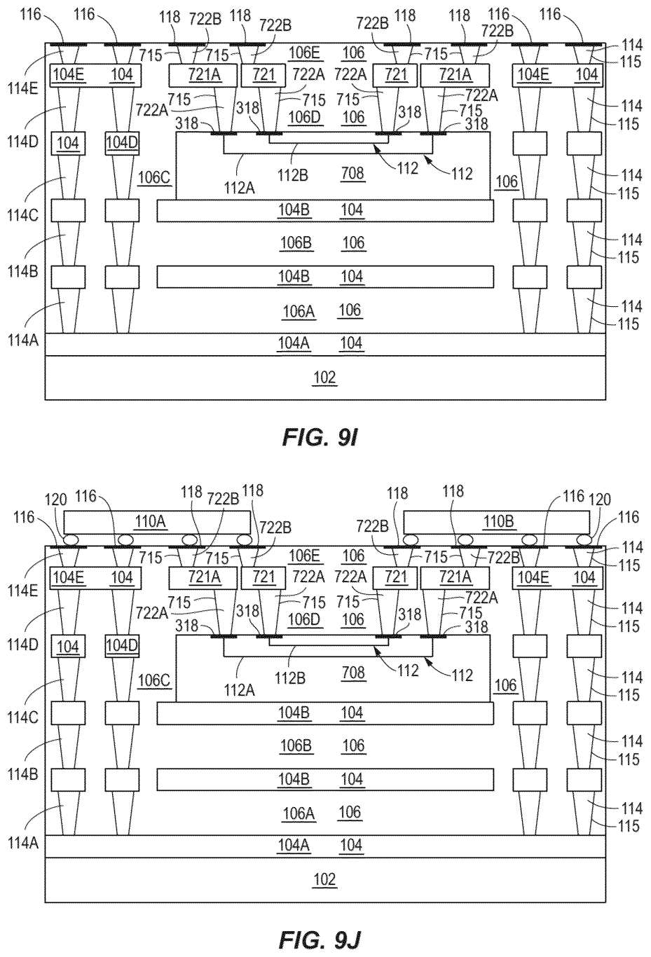

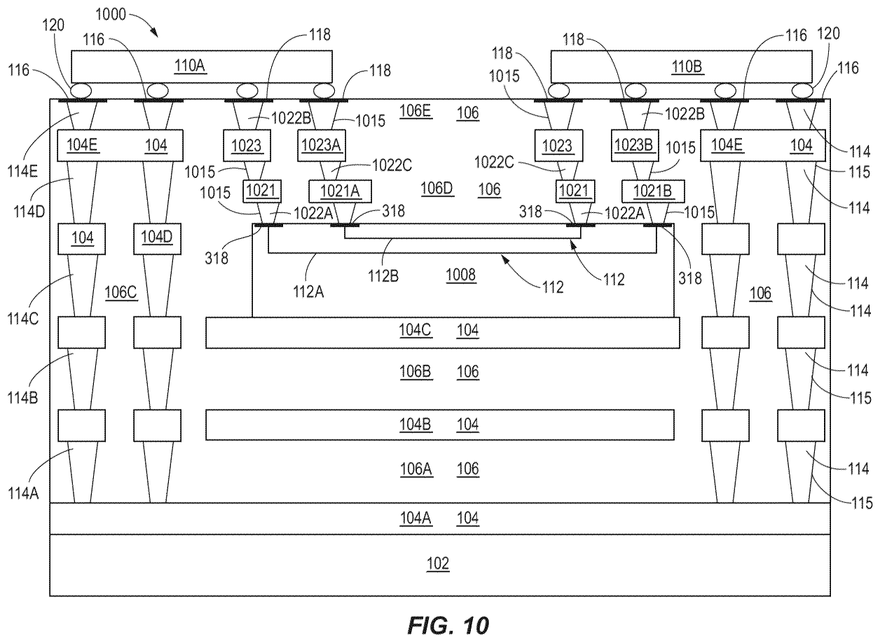

FIG. 10 is an intermediate via DTD interconnect 1000. The intermediate via DTD interconnect 1000 utilizes a first intermediate bridge interconnect layer 1021 and a second intermediate bridge interconnect layer 1023. The first intermediate bridge interconnect layer 1021 and the second intermediate bridge interconnect layer 1023 connect an intermediate via multi-die interconnect bridge 1008 to the plurality of bridge micro-bump pads 118. The first intermediate bridge interconnect layer 1021 includes a first die intermediate bridge interconnect layer 1021A and a die second intermediate bridge interconnect layer 1021B. The second intermediate bridge interconnect layer 1023 includes a first die intermediate bridge interconnect layer 1023A and a second die intermediate bridge interconnect layer 1023B.

One or more first bridge vias 1022A are disposed in bridge via channels 1015 to connect the bridge pads 318 to the first intermediate bridge interconnect layer 1021. One or more second bridge vias 1022B are disposed in the bridge via channels 1015 to connect the second intermediate bridge interconnect layer 1023 to the plurality of bridge micro-bump pads 118. One or more third bridge vias 1022C are disposed in the bridge via channels 1015 to connect the first intermediate bridge interconnect layer 1021 to the second intermediate bridge interconnect layer 1023. The first intermediate bridge interconnect layer 1021 and the second intermediate bridge interconnect layer 1023 span between the one or more first bridge vias 1022A, the one or more second bridge vias 1022B, the one or more third bridge vias 1022C to compensate for an x-axis shift, a y-axis shift, a rotational shift, or a combination thereof of the shifted multi-die interconnect bridge 1008. The shifted multi-die interconnect bridge 1008 may the rotated multi-die interconnect bridge 508, the x-axis shifted multi-die interconnect bridge 608, or a multi-die interconnect bridge having an x-axis shift, a y-axis shift, a rotational shift, or a combination thereof.

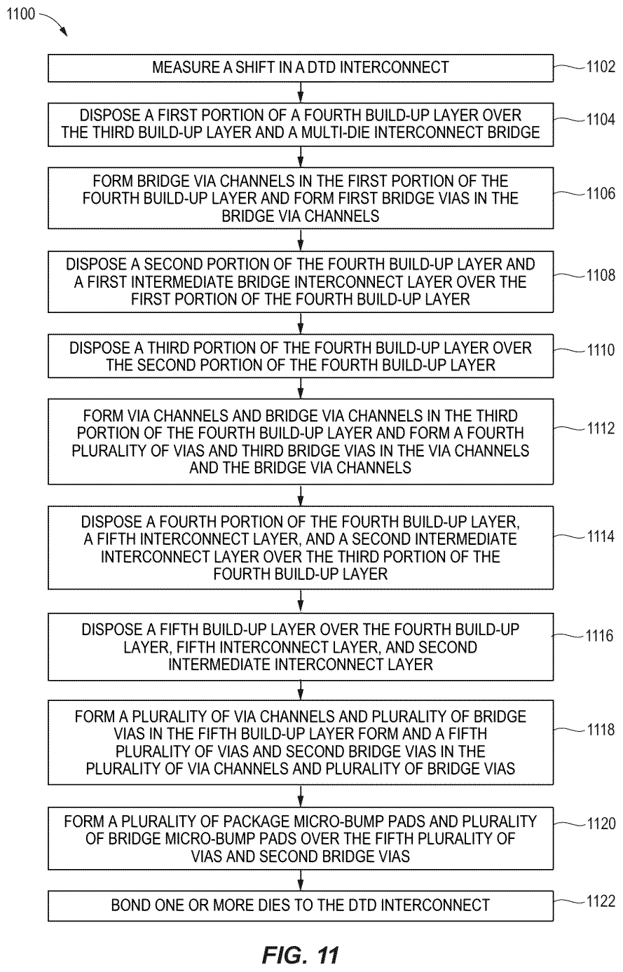

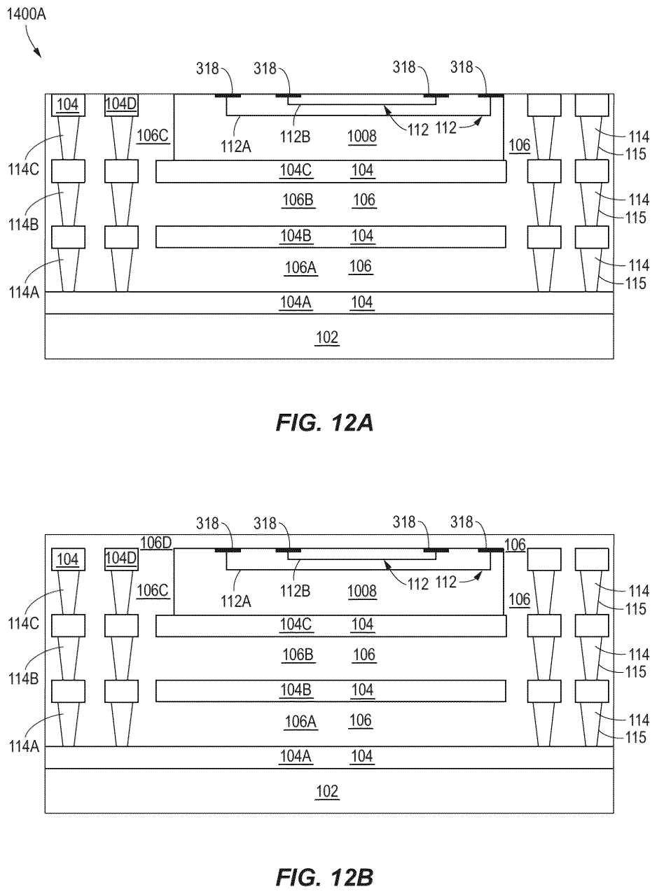

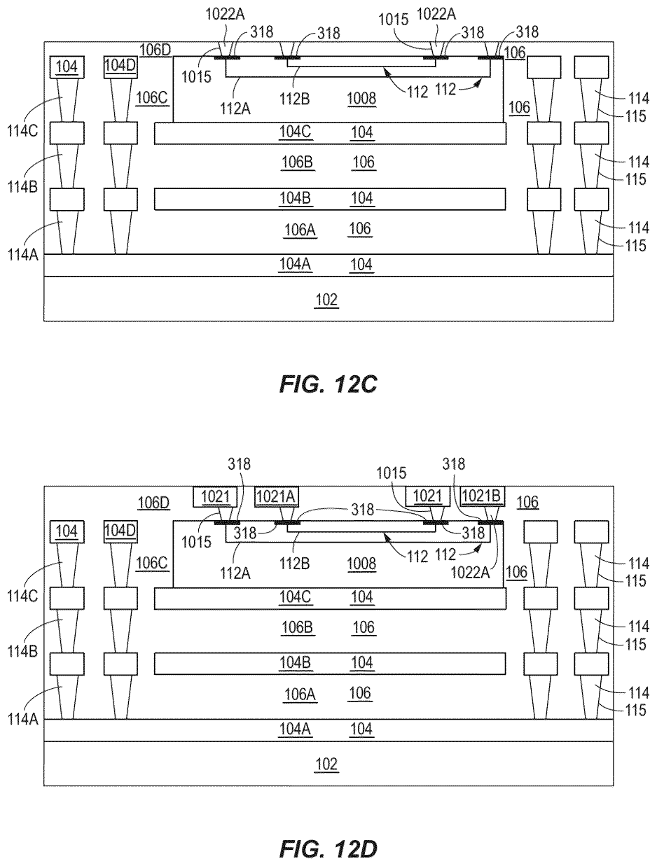

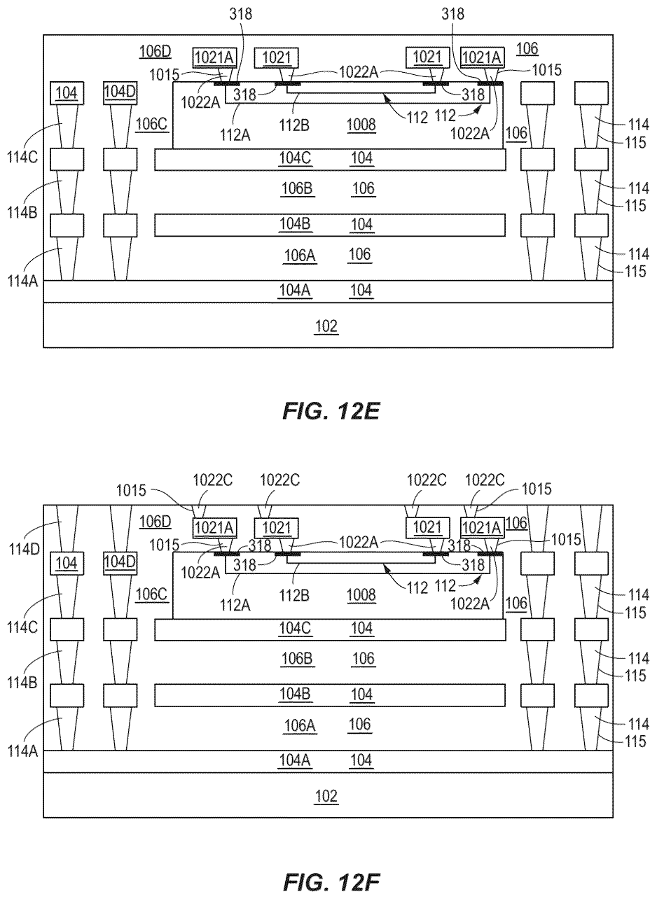

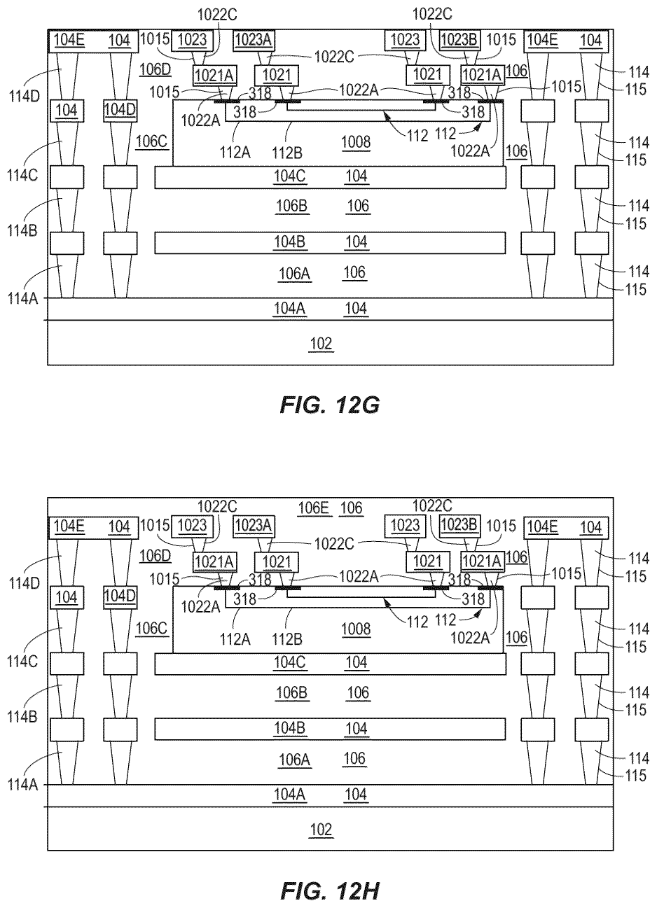

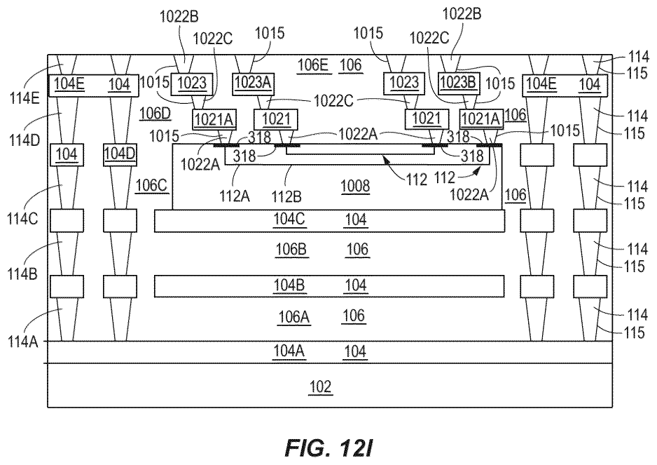

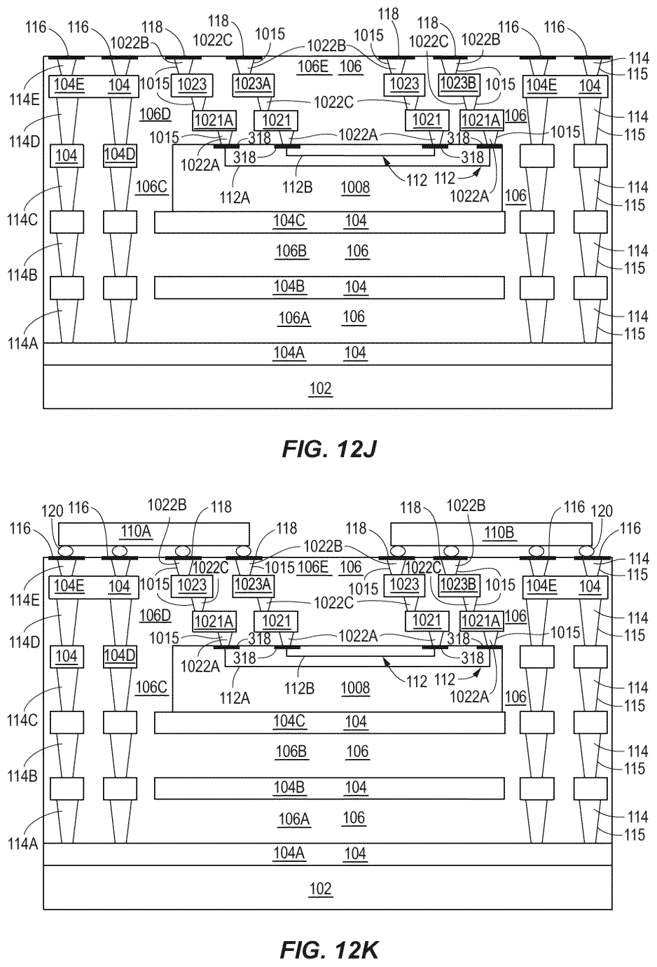

FIG. 11 is a flow diagram of a method 1100 of forming the intermediate via DTD interconnect 1000. FIG. 12A-12K are schematic, cross-sectional view of the intermediate via DTD interconnect 1000. The method 1100 may be performed using a photolithography system 1600A or a photolithography system 1600B.

At operation 1102 the shift of a partial intermediate via DTD interconnect 1200A, as shown in FIG. 12A, is measured. In one example, at operation 1102, the partial intermediate via DTD interconnect 1200A includes a substrate 102, a first interconnect layer 104A, a second interconnect layer 104B, a third interconnect layer 104C, a fourth interconnect layer 104D, a first build-up layer 106A, a second build-up layer 106B, and a third build-up layer 106C. The shifted multi-die interconnect bridge 1008 is embedded in the third build-up layer 106C.

The shift is measured within the photolithography system 1600A or the photolithography system 1600B using a metrology system, such as a camera. The metrology system measures the position of the plurality of bridge pads 318 of the shifted multi-die interconnect bridge 1008 against a nominal position. The nominal position is the position at which the micro-bumps 120 are configured to be connected to the plurality of bridge micro-bump pads 118. The metrology system calculates the differential between the measured position of the plurality of bridge pads 318 and the nominal position of the plurality of bridge micro-bump pads 118.

At operation 1104, as shown in FIG. 12B, a first portion of a fourth build-up layer 106D is disposed over the third build-up layer 106C and the shifted multi-die interconnect bridge 1008. The first portion of the fourth build-up layer 106D is deposited using lamination or slit coating.

At operation 1106, as shown in FIG. 12C, bridge via channels 1015 are formed in the first portion of the fourth build-up layer 106D and first bridge vias 1022A in the bridge via channels 1015. The plurality of bridge via channels 1015 are formed using a laser drilling machine or a lithography machine including a stepper, a laser direct imaging (LDI), or digital lithography.

At operation 1108, as shown in FIG. 12D, a second portion of the fourth build-up layer 106D and the first intermediate bridge interconnect layer 1021 are disposed over the first portion of the fourth build-up layer 106D.

At operation 1110, as shown in FIG. 12E, a third portion of the fourth build-up layer 106D is disposed over the second portion of the fourth build-up layer 106D.

At operation 1112, as shown in FIG. 12F, via channels 115 and bridge via channels 1015 are formed in the third portion of the fourth build-up layer 106D, and a plurality of fourth vias 114D and third bridge vias 1022C are formed in the via channels 115 and the bridge via channels 1015.

At operation 1114, as shown in FIG. 12G, a fourth portion of the fourth build-up layer 106D, a fifth interconnect layer 104E, and a second intermediate bridge interconnect layer 1023 are disposed over the third portion of the fourth build-up layer 106D.

At operation 1116, as shown in FIG. 12H, a fifth build-up layer 106E is disposed over the fourth build-up layer 106D, the fifth interconnect layer 104E, and a second intermediate bridge interconnect layer 1023.

At operation 1118, as shown in FIG. 121, a plurality of via channels 115 and a plurality of bridge channels 1015 are formed in the fifth build-up layer 106E, and a plurality of fifth vias 114E and second bridge vias 1022B are formed in the plurality of via channels and the plurality of bridge via channels 1015.

At operation 1120, as shown in FIG. 12J, a plurality of package micro-bump pads 116 and a plurality of bridge micro-bump pads 118 are disposed over the plurality of fifth vias 114E and the second bridge vias 1022B.

At operation 1122, as shown in FIG. 12K, one or more dies (e.g., a first die 110A and a second die 110B) are bonded to the intermediate via DTD interconnect 1000. The first die 110A and the second die 110B are bonded to the plurality of package micro-bump pads 116 and a plurality of bridge micro-bump pads 118 via micro-bumps 120.

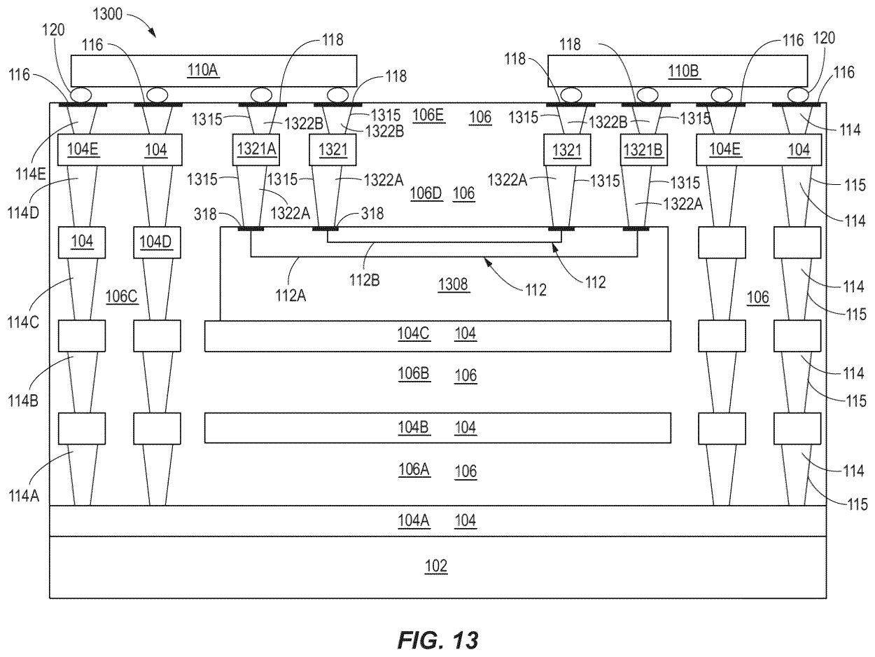

FIG. 13 is a shifted via DTD interconnect 1300. The shifted via DTD interconnect 1300 utilizes a shifted bridge interconnect layer 1321 to connect a first bridge vias 1322A and a second bridge vias 1322B. The shifted bridge interconnect layer 1321 includes a first shifted die interconnect layer 1321A and a second shifted die interconnect layer 1321B. The first die shifted interconnect layer 1321A is disposed between and electrically connects the multi-die interconnect bridge 1308 to the first die 110A. The second shifted die interconnect layer 1321B is disposed between and electrically connects the shifted multi-die interconnect bridge 1308 to the second die 110B. One or more first bridge vias 1322A are disposed in bridge via channels 1315 to connect the bridge pads 318 of the multi-die interconnect bridge 1308 to the bridge interconnect layer 1321. One or more second bridge vias 1322B are disposed in the bridge via channels 1315 to connect the shifted bridge interconnect layer 1321 to the plurality of bridge micro-bump pads 118. The shifted bridge interconnect layer 1321 spans between the one or more first bridge vias 1322A and the one or more second bridge vias 1322B to compensate for an x-axis shift, a y-axis shift, a rotational shift, or a combination thereof of the shifted multi-die interconnect bridge 1308. The shifted multi-die interconnect bridge 1308 may the rotated multi-die interconnect bridge 508, the x-axis shifted multi-die interconnect bridge 608, or a shifted multi-die interconnect bridge having an x-axis shift, a y-axis shift, a rotational shift, or a combination thereof.

The shifted DTD interconnect 1300 differs from the elongated DTD interconnect 700 in that the shifted bridge interconnect layer 1321 is not elongated to bridge between the first bridge vias 1322A and the second bridge vias 1322B. Instead of elongating the bridge interconnect layer, the shifted bridge interconnect layer 1321 is shifted with respect to the first bridge vias 1322A in order to span a shift distance between the first bridge vias 1322A and the second bridge vias 1322B caused by the shift in the shifted multi-die interconnect bridge 1308.

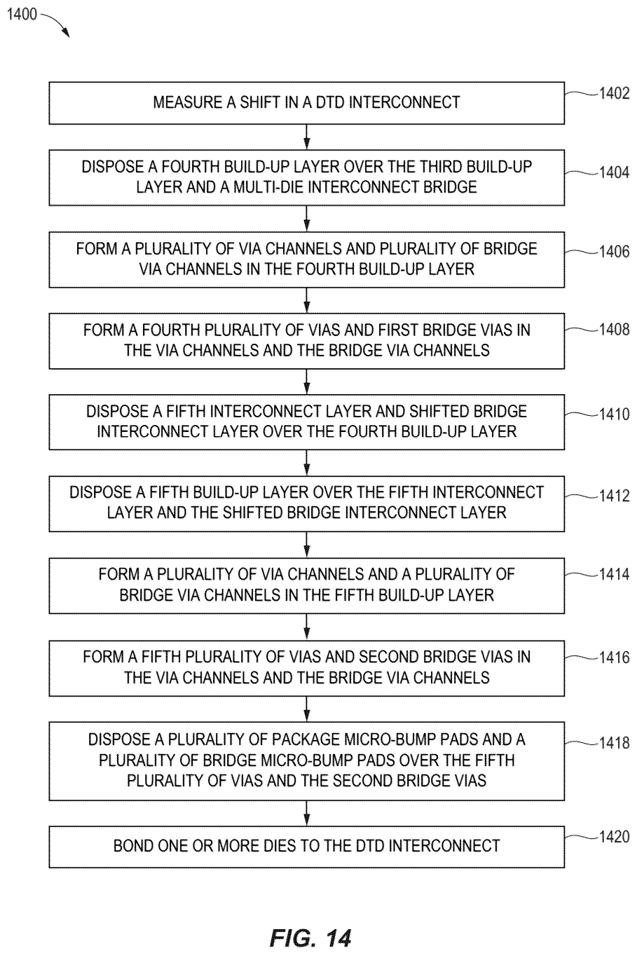

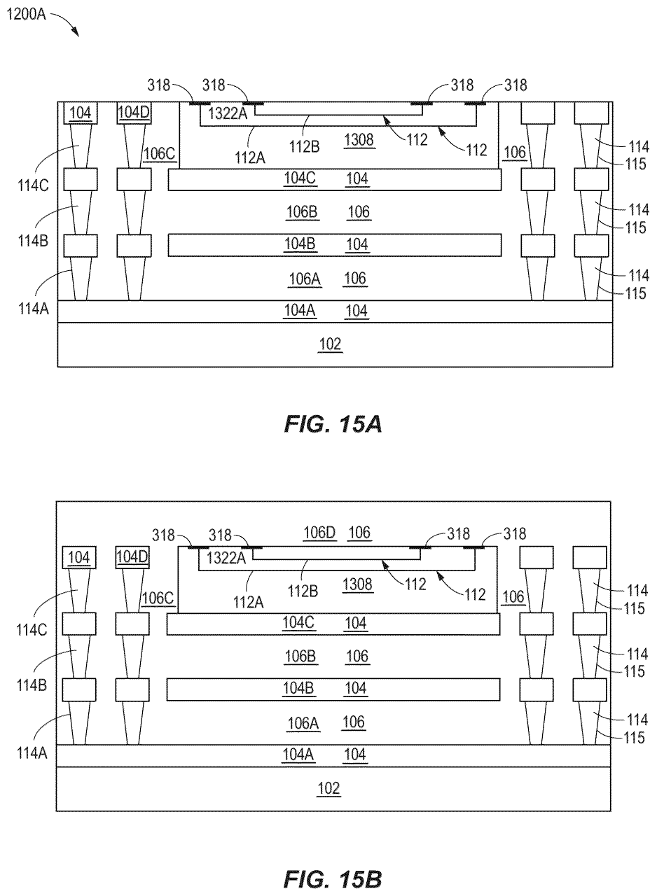

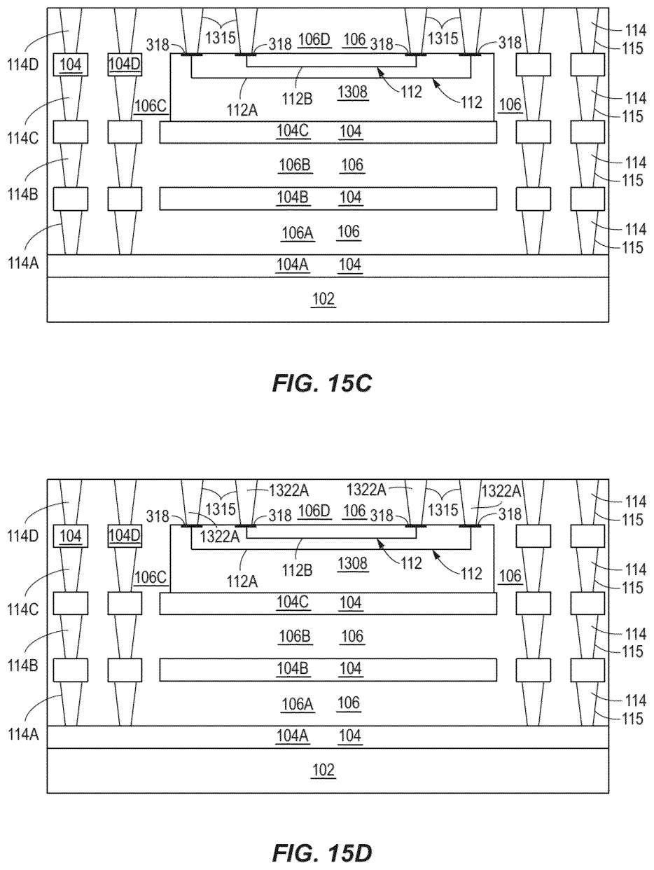

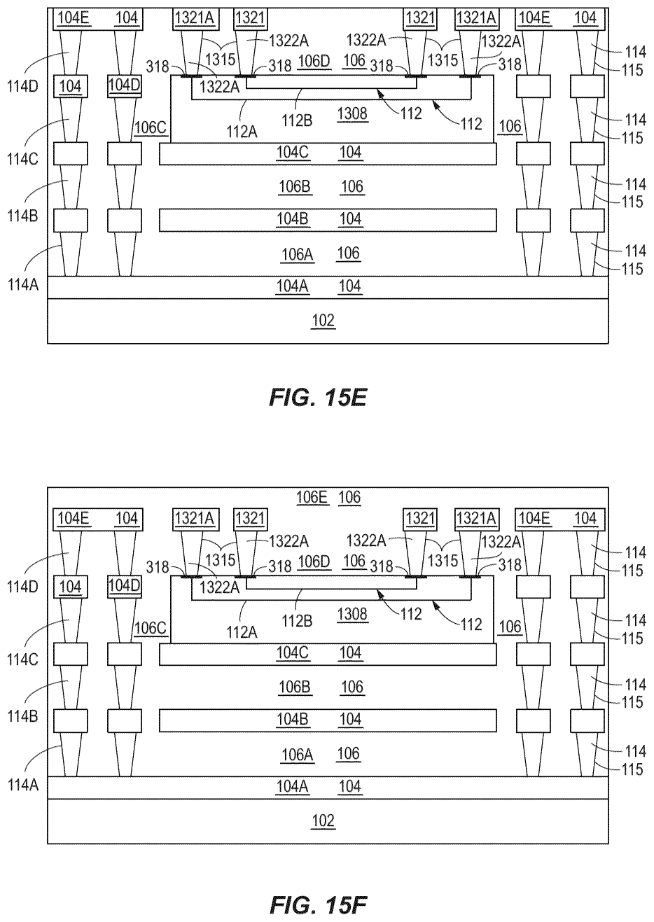

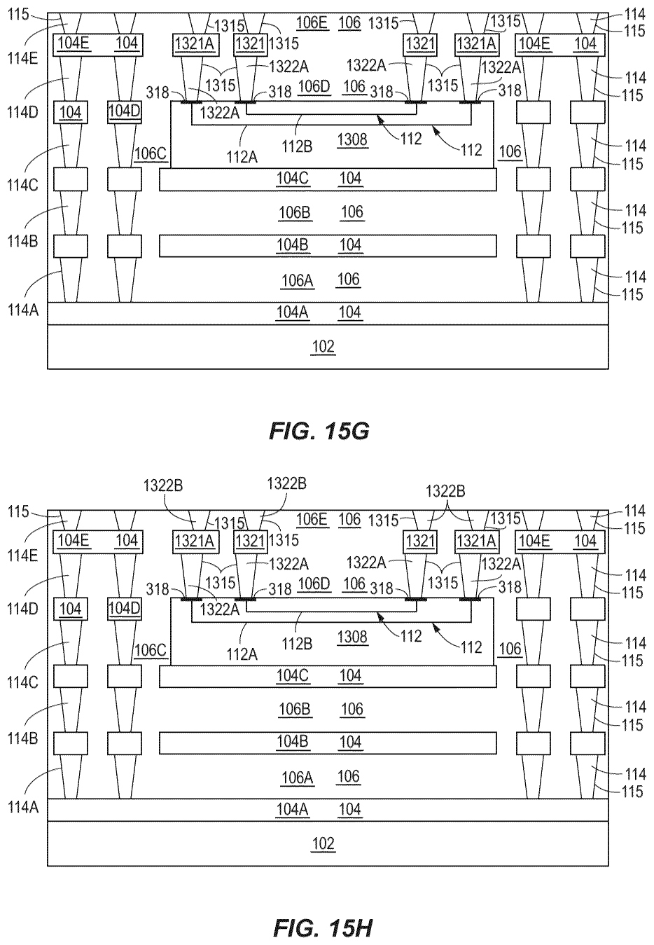

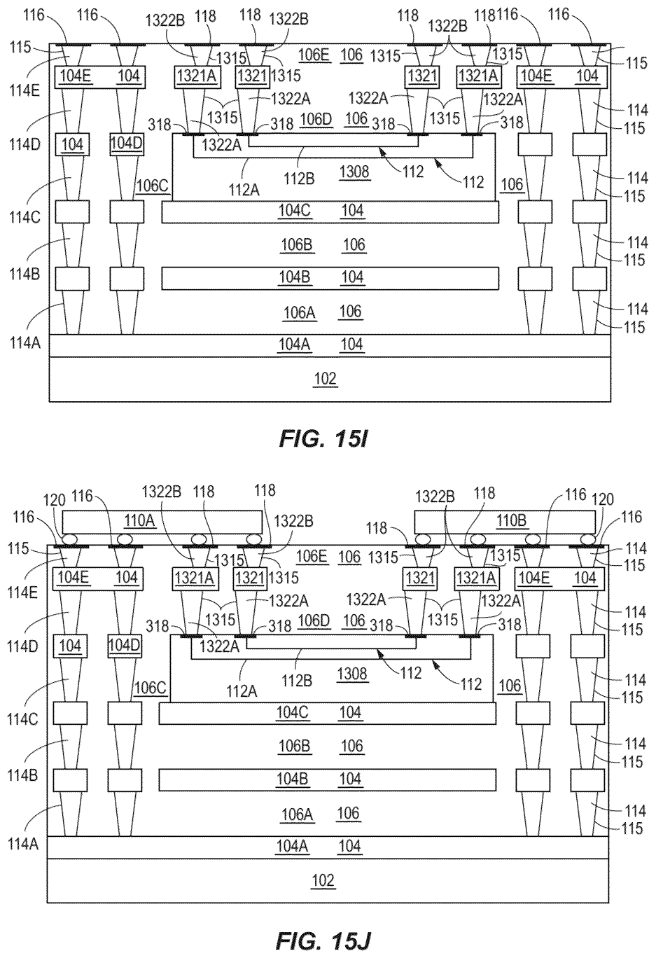

FIG. 14 is a flow diagram of a method 1400 of forming the intermediate via DTD interconnect 1300. FIG. 15A-15J are schematic, cross-sectional view of the intermediate via DTD interconnect 1300. The method 1400 may be performed using a photolithography system 1600A or a photolithography system 1600B.

At operation 1402 the shift of a partial intermediate via DTD interconnect 1300A, as shown in FIG. 15A, is measured. In one example, at operation 1402, the partial intermediate via DTD interconnect 1300A includes a substrate 102, a first interconnect layer 104A, a second interconnect layer 104B, a third interconnect layer 104C, a fourth interconnect layer 104D, a first build-up layer 106A, a second build-up layer 106B, and a third build-up layer 106C. The shifted multi-die interconnect bridge 1308 is embedded in the third build-up layer 106C.

The shift is measured within the photolithography system 1600A or the photolithography system 1600B using a metrology system, such as a camera. The metrology system measures the position of the plurality of bridge pads 318 of the shifted multi-die interconnect bridge 1308 against a nominal position. The nominal position is the position at which the micro-bumps 120 are configured to be connected to the plurality of bridge micro-bump pads 118. The metrology system calculates the differential between the measured position of the plurality of bridge pads 318 and the nominal position of the plurality of bridge micro-bump pads 118.

At operation 1404, as shown in FIG. 15B, a fourth build-up layer 106D is disposed over the third build-up layer 106C and the shifted multi-die interconnect bridge 1308. The fourth build-up layer 106D is deposited using lamination or slit coating.

At operation 1406, as shown in FIG. 15C, a plurality of via channels 115 and a plurality of bridge via channels 1015 are formed in the fourth build-up layer 106D. The plurality of via channels 115 and plurality of bridge via channels 1015 are formed using a laser drilling machine or a lithography machine including a stepper, a laser direct imaging (LDI), or digital lithography.

At operation 1408, as shown in FIG. 15D, a plurality of fourth vias 114D and first bridge vias 1022A are formed in the via channels 115 and the bridge via channels 1015.

At operation 1410, as shown in FIG. 15E, a fifth interconnect layer 104E and shifted bridge interconnect layer 1321 is disposed over the fourth build-up layer 106D.

At operation 1412, as shown in FIG. 15F, a fifth build-up layer 106E is disposed over the fifth interconnect layer 104E and shifted bridge interconnect layer 1321.

At operation 1414, as shown in FIG. 15G, a plurality of via channels 115 and a plurality of bridge via channels 1315 are formed in the fifth build-up layer 106E.

At operation 1416, as shown in FIG. 15H, a plurality of fifth vias 114E and second bridge vias 1322B are formed in the via channels 115 and the bridge via channels 1315.

At operation 1418, as shown in FIG. 151, a plurality of package micro-bump pads 116 and a plurality of bridge micro-bump pads 118 are disposed over the plurality of fifth vias 114E and second bridge vias 1322B.

At operation 1420, as shown in FIG. 15J, one or more dies (e.g., a first die 110A and a second die 110B) are bonded to the shifted DTD interconnect 1300. The first die 110A and the second die 110B are bonded to the plurality of package micro-bump pads 116 and a plurality of bridge micro-bump pads 118 via micro-bumps 120.

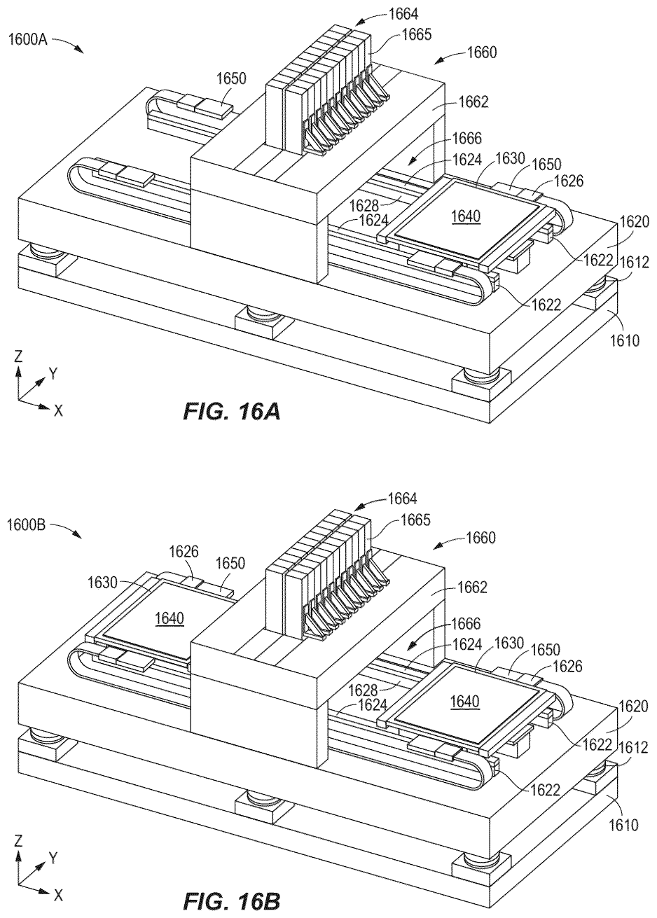

FIG. 16A is a perspective view of a photolithography system 1600A. The photolithography system 1600A includes a base frame 1610, a slab 1620, a stage 1630, and a processing apparatus 1660. The base frame 1610 rests on the floor of a fabrication facility and supports the slab 1620. Passive air isolators 1612 are positioned between the base frame 1610 and the slab 1620. In one embodiment, the slab 1620 is a monolithic piece of granite, and the stage 1630 is disposed on the slab 1620. A substrate 1640 is supported by the stage 1630. A plurality of holes (not shown) are formed in the stage 1630 for allowing a plurality of lift pins (not shown) to extend therethrough. In some embodiments, the lift pins rise to an extended position to receive the substrate 1640, such as from one or more transfer robots (not shown). The one or more transfer robots are used to load and unload a substrate 1640 from the stage 1630.

The substrate 1640 comprises any suitable material, for example, quartz used as part of a flat panel display. In other embodiments, the substrate 1640 is made of other materials. In some embodiments, the substrate 1640 has a photoresist layer formed thereon. A photoresist is sensitive to radiation. A positive photoresist includes portions of the photoresist, which when exposed to radiation, will be respectively soluble to photoresist developer applied to the photoresist after the pattern is written into the photoresist. A negative photoresist includes portions of the photoresist, which when exposed to radiation, will be respectively insoluble to photoresist developer applied to the photoresist after the pattern is written into the photoresist. The chemical composition of the photoresist determines whether the photoresist will be a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. In this manner, the pattern is created on a surface of the substrate 1640 to form the electronic circuitry.

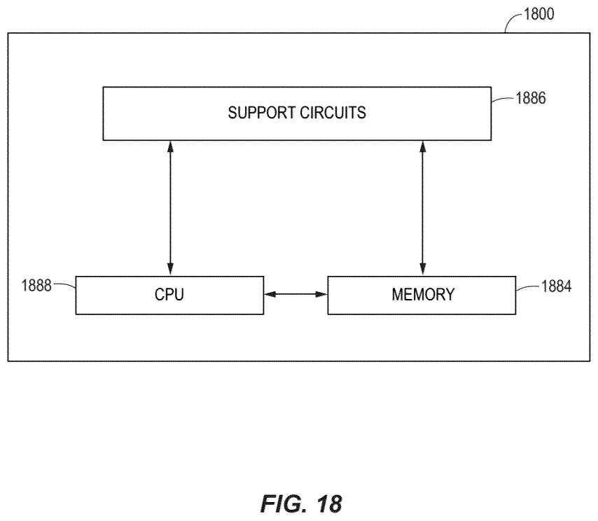

The photolithography system 1600A includes a pair of supports 1622 and a pair of tracks 1624. The pair of supports 1622 are disposed on the slab 1620 and are a single piece of material. The pair of tracks 1624 is supported by the pair of the supports 1622, and the stage 1630 moves along the tracks 1624 in the X-direction. In one embodiment, the pair of tracks 1624 is a pair of parallel magnetic channels. As shown, each track 1624 of the pair of tracks 1624 is linear. In other embodiments, one or more track 1624 is non-linear. An encoder 1626 is coupled to the stage 1630 in order to provide location information to a controller 1800, as shown in FIG. 18.

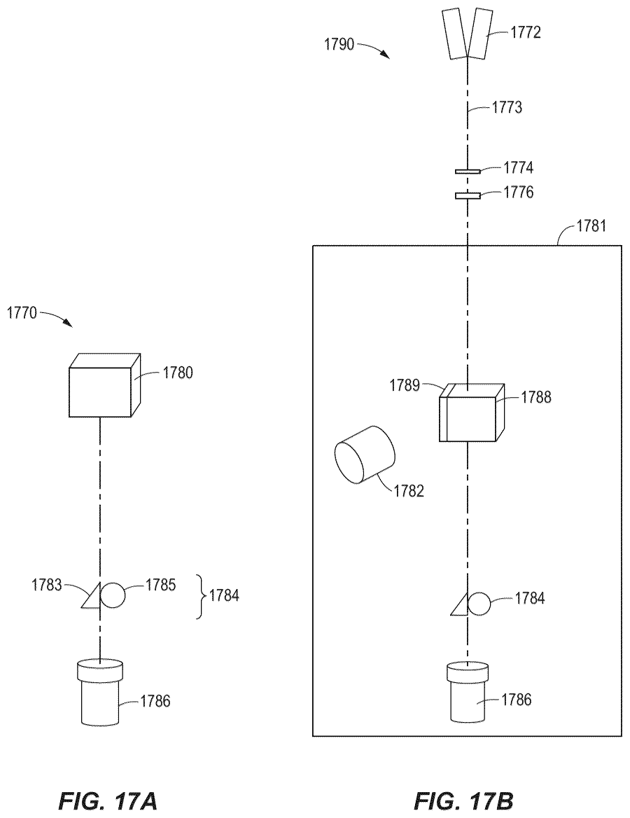

The processing apparatus 1660 includes a support 1662 and a processing unit 1664. The support 1662 is disposed on the slab 1620 and includes an opening 1666 for the stage 1630 to pass under the processing unit 1664. The processing unit 1664 is supported by the support 1662. In one embodiment, the processing unit 1664 is a pattern generator configured to expose a photoresist in a photolithography process. In some embodiments, the pattern generator is configured to perform a maskless lithography process. The processing unit 1664 includes a plurality of image projection apparatus (shown in FIGS. 17A and 17B). In one embodiment, the processing unit 1664 contains as many as 84 image projection apparatus. Each image projection apparatus is disposed in a case 1665. The processing apparatus 1660 is useful to perform maskless direct patterning.

During operation, the stage 1630 moves in the X-direction from a loading position, as shown in FIG. 16A, to a processing position. The processing position is one or more positions of the stage 1630 as the stage 1630 passes under the processing unit 1664. During operation, the stage 1630 is be lifted by a plurality of air bearings (not shown) and moves along the pair of tracks 1624 from the loading position to the processing position. A plurality of vertical guide air bearings (not shown) are coupled to the stage 1630 and positioned adjacent an inner wall 1628 of each support 1622 in order to stabilize the movement of the stage 1630. The stage 1630 also moves in the Y-direction by moving along a track 1650 for processing and/or indexing the substrate 1640. The stage 1630 is capable of independent operation and can scan a substrate 1640 in one direction and step in the other direction.

A metrology system measures the X and Y lateral position coordinates of each of the stage 1630 in real time so that each of the plurality of image projection apparatus can accurately locate the patterns being written in a photoresist covered substrate. The metrology system also provides a real-time measurement of the angular position of each of the stage 1630 about the vertical or Z-axis. The angular position measurement can be used to hold the angular position constant during scanning by means of a servo mechanism or it can be used to apply corrections to the positions of the patterns being written on the substrate 1640 by the image projection apparatus 1770, shown in FIGS. 17A and 17B. These techniques may be used in combination.

FIG. 16B is a perspective view of a photolithography system 1600B. The photolithography system 1600B is similar to the photolithography system 1600A; however, the photolithography system 1600B includes two stages 1630. Each of the two stages 1630 is capable of independent operation and can scan a substrate 1640 in one direction and step in the other direction. In some embodiments, when one of the two stages 1630 is scanning a substrate 1640, the other of the two stages 1630 is unloading an exposed substrate and loading the next substrate to be exposed.

While FIGS. 17A and 17B depict two embodiments of a photolithography system, other systems and configurations are also contemplated herein. For example, photolithography systems including any suitable number of stages are also contemplated.

FIG. 17A is a perspective schematic view of an image projection apparatus 1770, which is useful for a photolithography system, such as system 1600A or system 1600B. The image projection apparatus 1770 includes one or more spatial light modulators 1780, an alignment and inspection system 1784 including a focus sensor 1783 and a camera 1785, and projection optics 1786. The components of image projection apparatus vary depending on the spatial light modulator being used. Spatial light modulators include, but are not limited to, microLEDs, digital micromirror devices (DMDs) and liquid crystal displays (LCDs).

In operation, the spatial light modulator 1780 is used to modulate one or more properties of the light, such as amplitude, phase, or polarization, which is projected through the image projection apparatus 1770 and to a substrate, such as the substrate 1640. The alignment and inspection system 1784 is used for alignment and inspection of the components of the image projection apparatus 1770. In one embodiment, the focus sensor 1783 includes a plurality of lasers which are directed through the lens of the camera 1785 and the back through the lens of the camera 1785 an imaged onto sensors to detect whether the image projection apparatus 1770 is in focus. The camera 1785 is used to image the substrate, such as substrate 1640, to ensure the alignment of the image projection apparatus 1770 and photolithography system 1600A or 1600B is correct or within an predetermined tolerance. The projection optics 1786, such as one or more lenses, is used to project the light onto the substrate, such as the substrate 1640.

FIG. 17B is an image project apparatus 1781. In the embodiment shown in FIG. 17B, the image projection apparatus 1781 uses one or more DMDs 1789 as the spatial light modulator(s). The image projection apparatus 1781 is part of an image projection system 1790, which includes a light source 1772, an aperture 1774, and a lens 1776. The image projection apparatus 1781 includes a frustrated prism assembly 1788, one or more DMDs 1789 (one is shown), and a light dump 1782, in addition to the alignment and inspection system 1784 and the projection optics 1786. The light source 1772 is any suitable light source, such as a light emitting diode (LED) or a laser, capable of producing a light beam having predetermined wavelength. In one or more embodiments, the light beam has with a wavelength in a range from about 400 nm to about 750 nm. In other embodiments, the predetermined wavelength is in the blue or near ultraviolet (UV) range, such as less than 450 nm. For example, the light beam has a wavelength in a range from about 360 nm to about 410 nm. The frustrated prism assembly 1788 includes a plurality of reflective surfaces. The projection optics 1786 is, as an example, a 6× objective lens.

During operation of the image projection apparatus 1781 shown in FIG. 17B, a light beam 1773 having a predetermined wavelength, such as a wavelength in the blue range, is produced by the light source 1772. The light beam 1773 is reflected to the DMD 1789 by the frustrated prism assembly 1788. The DMD includes a plurality of mirrors, and the number of mirrors corresponds to the number of pixels to be projected. In one implementation, the DMD includes 2,560×1,600 mirrors. The plurality of mirrors are individually controllable, and each mirror of the plurality of mirrors is at an “on” position or “off” position, based on the mask data provided to the DMD 1789 by the controller (not shown). In one implementation, the combination of mirrors in “on” positions and “off” positions forms the desired pattern. When the light beam 1773 reaches the mirrors of the DMD 1789, the mirrors that are at “on” position reflect the light beam 1773, e.g., forming the plurality of write beams, to the projection optics 1786. The projection optics 1786 then projects the write beams to the surface of the substrate 1640. The mirrors that are at “off” position reflect the light beam 1773 to the light dump 1782 instead of the surface of the substrate 1640.

FIG. 18 is a controller 1800. The controller 1800 is configured to receive data or input from the photolithography system 1600A or photolithography system 1600B. The controller includes a memory 1884, support circuits 1886, and a central processing unit (CPU) 1888 (e.g., a processor) that are coupled to one another. The controller 1800 controls various components of the photolithography system 1600A or photolithography system 1600B directly, or via other computers and/or controllers.

The CPU 1888 is any form of general purpose computer processor that is used in an industrial setting for controlling the photolithography system 1600A or photolithography system 1600B, such as a programmable logic controller (PLC), supervisory control and data acquisition (SCADA) systems, general purpose graphics processing unit (GPU), or other suitable industrial controller. The memory 1884, or non-transitory computer readable medium, is one or more of a readily available memory such as random access memory (RAM), dynamic random access memory (DRAM), static RAM (SRAM), and synchronous dynamic RAM (SDRAM) (e.g., DDR1, DDR2, DDR3, DDRL3, LPDDR3, DDR4, LPDDR4, and the like)), read only memory (ROM), floppy disk, hard disk, flash drive, or any other form of digital storage, local or remote. The support circuits 1886 of the controller 1800 are coupled to the CPU 1888 for supporting the CPU 1888. The support circuits 1886 include cache, power supplies, clock circuits, input/output circuitry and subsystems, and the like.

The memory 1884 contains instructions that, when executed by the CPU 1888, facilitates execution of the methods 800, 1100, 1400. The instructions in the memory 1884 are in the form of a program product such as a program that implements the method of the present disclosure. The program code of the program product may conform to any one of a number of different programming languages.

Operational parameters and operations are stored in the memory 1884 as a software routine that is executed or invoked to turn the photolithography system 1600A or photolithography system 1600B. The controller 1800 is configured to conduct any of the operations described herein. The instructions stored on the memory 1884, when executed, cause one or more of the operations (such as the operations of methods 800, 1100, 1400) described herein to be conducted in relation to the photolithography system 1600A or photolithography system 1600B.

The various operations described herein can be conducted automatically using the controller 1800, or can be conducted automatically or manually with certain operations conducted by a user.

In summary, a method of compensating for X/Y drift in high density die-to-die interconnects is disclosed. The method utilizes a maskless direct-writing tool that calculates, based on micro-bump pitch, via dimensions, and lithography overlay error, how many steps are needed to gradually rotate the build-up layers to return a top layer micro-bump grid to the nominal X/Y location. The method compensates for randomized die shift/rotation error, and restores the top layer to the nominal X/Y position in a controlled manner via the maskless direct-writing lithography tool.

It is contemplated that one or more aspects disclosed herein may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method of forming a die-to-die (DTD) interconnect, comprising:
measuring a shift in a multi-die interconnect bridge of a partial DTD interconnect, wherein the partial DTD interconnect comprises:
a substrate;
a plurality of build-up layers disposed over the substrate;
a plurality of interconnect layers disposed between the plurality of build-up layers;
a plurality of vias disposed in via channels connecting the plurality of interconnect layers; and
the multi-die interconnect bridge disposed in a build-up layer of the plurality of build-up layers;
calculating, using a maskless direct-writing tool, a number of steps to return a plurality of bridge micro-bump pads to a nominal position based on:
a micro-bump pitch;
dimensions of a first plurality of vias, a second plurality of vias, a first bridge vias, and a second bridge vias; and
a lithography overlay error;
compensating for shift in the multi-die interconnect bridge; and
restoring the plurality of bridge micro-bump pads to the nominal position in a controlled manner via the maskless direct-writing lithography tool; and
bonding one or more dies to the DTD interconnect, wherein an elongated bridge interconnect is configured to span a distance between a position of a plurality of bridge pads of the multi-die interconnect bridge and a nominal position of the plurality of bridge pads caused by a shift in the multi-die interconnect bridge.

2. The method of claim 1, wherein restoring the plurality of bridge micro-bump pads to the nominal position in a controlled manner via the maskless direct-writing lithography tool comprises:
disposing a first build-up layer over the plurality of build-up layers and the multi-die interconnect bridge;
forming a plurality of via channels and bridge via channels in the first build-up layer;
forming a first plurality of vias and a first plurality of bridge vias in the via channels and the bridge via channels;
disposing first interconnect layer over the first plurality of vias and an elongated bridge interconnect over the first plurality of bridge via channels;
disposing a second build-up layer over the first build-up layer;
forming a plurality of via channels and bridge via channels in the second build-up layer;
forming a plurality of via channels and bridge via channels in the first build-up layer;
forming a second plurality of vias and a second plurality of bridge vias in the via channels and the bridge via channels; and
dispose a plurality of package micro-bump pads over the second plurality of vias and a plurality of bridge micro-bump pads over the second bridge vias, wherein the second plurality of vias are aligned with the package micro-bump pads and the second plurality of bridge vias are aligned with the plurality of bridge micro-bump pads.

3. The method of claim 1, wherein the shift in the multi-die interconnect bridge is a X-axis shift, a Y-axis shift, a rotational shift, or a combination thereof.

4. The method of claim 1, wherein the shift in the multi-die interconnect bridge is measured within a photolithography system using a metrology system.

5. The method of claim 1, wherein the one or more dies are connected to a plurality of package micro-bump pads and to the plurality of bridge micro-bump pads by a plurality of bumps using thermo-compression bonding.

6. The method of claim 5, wherein the bumps include tin-lead (SnPb) materials, tin-silver (SnAg) materials, tin-silver-copper (SAC) materials, gold-tin materials (AuSn), copper pillar (Cu-pillar), alloys thereof, or combinations thereof.

7. The method of claim 5, wherein the plurality of bumps have a micro-bump pitch of less than 10 microns.

8. A method for forming a die-to-die (DTD) interconnect, comprising:
measuring a shift in a multi-die interconnect bridge of a partial DTD interconnect, wherein the partial DTD interconnect comprises:
a substrate;
a plurality of build-up layers disposed over the substrate;
a plurality of interconnect layers disposed between the plurality of build-up layers;
a plurality of vias disposed in via channels connecting the plurality of interconnect layers; and
the multi-die interconnect bridge disposed in a build-up layer of the plurality of build-up layers;
calculating, using a maskless direct-writing tool, a number of steps to return a plurality of bridge micro-bump pads to the nominal position based on:
a micro-bump pitch;
dimensions of a first plurality of vias, a second plurality of vias, a first bridge vias, and a second bridge vias; and
a lithography overlay error;
compensating for shift in the multi-die interconnect bridge; and
restoring the plurality of bridge micro-bump pads to the nominal position in a controlled manner via the maskless direct-writing lithography tool; and
bonding one or more dies to the DTD interconnect, wherein a first intermediate interconnect layer and a second intermediate interconnect layer is configured to span a distance between a position of a plurality of bridge pads of the multi-die interconnect bridge and a nominal position of the plurality of bridge pads caused by a shift in the multi-die interconnect bridge.

9. The method of claim 8, wherein of bridge micro-bump pads to the nominal position in a controlled manner via the maskless direct-writing lithography tool comprises:
disposing a first portion of a first build-up layer over the plurality of build-up layers and the multi-die interconnect bridge;
forming a plurality of bridge via channels in the first portion of the first build-up layer;
forming a first plurality of bridge vias in the bridge via channels;
disposing a second portion of the first build-up layer and a first intermediate interconnect layer over the first portion of the first build-up layer and the first bridge vias;
disposing a third portion of the first build-up layer over the second portion of the first build-up layer;
forming a plurality of via channels in the first build-up layer and bridge via channels in the third portion of the first build-up layer;
forming a first plurality of vias in the via channels and a second plurality of bridge vias in the bridge via channels;
dispose a fourth portion of the first build-up layer, a first interconnect layer, and a second intermediate interconnect layer over the third portion of the first build-up layer;
dispose a second build-up layer over the first build-up layer, first interconnect layer, and second intermediate interconnect layer;
form a plurality of via channels and a plurality of bridge via channels in the second build-up layer;
forming a second plurality of vias in the via channels and a second plurality of bridge vias in the bridge via channels; and
disposing a plurality of package micro-bump pads over the second plurality of vias and a plurality of bridge micro-bump pads over the second bridge vias, wherein the second plurality of vias are aligned with the package micro-bump pads and the second plurality of bridge vias are aligned with the plurality of bridge micro-bump pads.

10. The method of claim 8, wherein the shift in the multi-die interconnect bridge is a X-axis shift, a Y-axis shift, a rotational shift, or a combination thereof.

11. The method of claim 8, wherein the shift in the multi-die interconnect bridge is measured within a photolithography system using a metrology system.

12. The method of claim 8, wherein the one or more dies are connected to a plurality of package micro-bump pads and to the plurality of bridge micro-bump pads by a plurality of bumps using thermo-compression bonding.

13. The method of claim 12, wherein the bumps include tin-lead (SnPb) materials, tin-silver (SnAg) materials, tin-silver-copper (SAC) materials, gold-tin materials (AuSn), copper pillar (Cu-pillar), alloys thereof, or combinations thereof.

14. The method of claim 12, wherein the plurality of bumps have a micro-bump pitch of less than 10 microns.

15. A method for forming a die-to-die (DTD) interconnect, comprising:
measuring a shift in a multi-die interconnect bridge of a partial DTD interconnect, wherein the partial DTD interconnect comprises:
a substrate;
a plurality of build-up layers disposed over the substrate;
a plurality of interconnect layers disposed between the plurality of build-up layers;
a plurality of vias disposed in via channels connecting the plurality of interconnect layers; and
the multi-die interconnect bridge disposed in a build-up layer of the plurality of build-up layers;
calculating, using a maskless direct-writing tool, a number of steps to return a plurality of bridge micro-bump pads to the nominal position based on:
a micro-bump pitch;
dimensions of a first plurality of vias, a second plurality of vias, a first bridge vias, and a second bridge vias; and
a lithography overlay error;
compensating for shift in the multi-die interconnect bridge; and
restoring the plurality of bridge micro-bump pads to the nominal position in a controlled manner via the maskless direct-writing lithography tool; and
bonding one or more dies to the DTD interconnect, wherein a shifted bridge interconnect is configured to span a distance caused by a shift in the multi-die interconnect bridge.

16. The method of claim 15, wherein restoring a plurality of bridge micro-bump pads to the nominal position in a controlled manner via the maskless direct-writing lithography tool comprises:
disposing a first build-up layer over the plurality of build-up layers and the multi-die interconnect bridge;
forming a plurality of via channels and bridge via channels in the first build-up layer;
forming a first plurality of vias and a first plurality of bridge vias in the via channels and the bridge via channels;
disposing first interconnect layer over the first plurality of vias and a shifted bridge interconnect over the first plurality of bridge via channels;
disposing a second build-up layer over the first build-up layer;
forming a plurality of via channels and bridge via channels in the second build-up layer;
forming a second plurality of vias and a second plurality of bridge vias in the via channels and the bridge via channels; and
disposing a plurality of package micro-bump pads over the second plurality of vias and a plurality of bridge micro-bump pads over the second bridge vias, wherein the second plurality of vias are aligned with the package micro-bump pads and the second plurality of bridge vias are aligned with the plurality of bridge micro-bump pads.

17. The method of claim 15, wherein the shift in the multi-die interconnect bridge is a X-axis shift, a Y-axis shift, a rotational shift, or a combination thereof.

18. The method of claim 15, wherein the one or more dies are connected to a plurality of package micro-bump pads and to the plurality of bridge micro-bump pads by a plurality of bumps using thermo-compression bonding.

19. The method of claim 18, wherein the bumps include tin-lead (SnPb) materials, tin-silver (SnAg) materials, tin-silver-copper (SAC) materials, gold-tin materials (AuSn), copper pillar (Cu-pillar), alloys thereof, or combinations thereof.

20. The method of claim 18, wherein the plurality of bumps have a micro-bump pitch of less than 10 microns.
